(19) United States
(12) Patent Application Publication
(10) Pub. No.: US 2026/0238236 A1
(43) Pub. Date: Aug. 13, 2026

(54) ELECTRONIC DEVICE COMPRISING ANTENNA

(71) Applicant: SAMSUNG ELECTRONICS CO., LTD., Suwon-si (KR)

(72) Inventors: Namjun CHO, Suwon-si (KR); Hyoseok NA, Suwon-si (KR)

(21) Appl. No.: 19/646,270

(22) Filed: Apr. 13, 2026

Related U.S. Application Data
(63) Continuation of application No. PCT/KR2024/015434, filed on Oct. 11, 2024.

(30) Foreign Application Priority Data
Oct. 13, 2023 (KR) 10-2023-0137215
Dec. 5, 2023 (KR) 10-2023-0174986

(51) Int. Cl. H04B 1/00; H04B 1/40; H05K 1/181; H05K 7/14

(52) U.S. Cl. CPC H04B 1/0064; H04B 1/40; H05K 1/181; H05K 7/1427; H05K 2201/10098

(57) ABSTRACT

An electronic device may include: a plurality of antennas including a first antenna and a second antenna; an RF transceiver; a first RFFE module electrically connected to the RF transceiver and configured to transmit or receive a signal; a second RFFE module electrically connected to the RF transceiver and configured to receive a signal; and a plurality of switching circuits including a first switching circuit connected to the first RFFE module and a second switching circuit connected to the second RFFE module, wherein the first switching circuit may be configured to selectively connect the first RFFE module with the first antenna in a first connection mode or with the second antenna in a second connection mode, and the second switching circuit may be configured to selectively connect the second RFFE module with the second antenna in the first connection mode or with the first antenna in the second connection mode.

### CROSS-REFERENCE TO RELATED APPLICATIONS

This application is a continuation of International Application No. PCT/KR2024/015434 designating the United States, filed on Oct. 11, 2024, in the Korean Ministry of Intellectual Property Receiving Office and claiming priority to Korean Patent Application Nos. 10-2023-0137215, filed on Oct. 13, 2023, and 10-2023-0174986, filed on Dec. 5, 2023, in the Korean Ministry of Intellectual Property, the disclosures of each of which are incorporated by reference herein in their entireties.

### BACKGROUND

### Field

The disclosure relates to an electronic device comprising an antenna.

### Description of Related Art

An electronic device may comprise a radio frequency front end (RFFE) module to transmit or receive a signal. The electronic device may transmit a signal through an antenna connected to the RFFE module.

The above-described information may be provided as a related art for the purpose of helping to understand the present disclosure. No assertion or determination is made as to whether any of the above-described information may be applied as a prior art related to the present disclosure.

### SUMMARY

According to an example embodiment, an electronic device is provided. The electronic device may comprise: a plurality of antennas including a first antenna and a second antenna, a radio frequency (RF) transceiver, a first radio frequency front end (RFFE) module comprising circuitry electrically connected to the RF transceiver and configured to transmit and/or receive a signal, a second RFFE module comprising circuitry electrically connected to the RF transceiver and configured to receive a signal, and a plurality of switching circuits including a first switching circuit connected to the first RFFE module and a second switching circuit connected to the second RFFE module. The first switching circuit may be configured to selectively connect the first RFFE module to the first antenna in a first connection mode or to the second antenna in a second connection mode. The second switching circuit may be configured to selectively connect the second RFFE module to the second antenna in the first connection mode or to the first antenna in the second connection mode.

According to an example embodiment, an electronic device is provided. The electronic device may comprise a housing. The housing may include a first conductive portion comprising a conductive material and a second conductive portion comprising a conductive material formed on an outer lateral surface of the housing. The electronic device may include: a radio frequency (RF) transceiver, a first radio frequency front end (RFFE) module comprising circuitry electrically connected to the RF transceiver and configured to transmit and/or receive a signal, a second RFFE module comprising circuitry electrically connected to the RF transceiver and configured to receive a signal, a first switching circuit connected to the first RFFE module, and a second switching circuit connected to the second RFFE module. The first switching circuit may be configured to selectively connect the first RFFE module to the first conductive portion or the second conductive portion. The second switching circuit may be configured to selectively connect the second RFFE module to the first conductive portion or the second conductive portion.

According to an example embodiment, an electronic device is provided. The electronic device may comprise: a first housing, a second housing rotatably coupled to the first housing, a first antenna included in the first housing, a second antenna included in the second housing, a first printed circuit board (PCB) included in the first housing, a second PCB included in the second housing, a radio frequency (RF) transceiver disposed on the first PCB, a first radio frequency front end (RFFE) module comprising circuitry, disposed on the first PCB, electrically connected to the RF transceiver, and configured to transmit and/or receive a signal, a second RFFE module comprising circuitry, disposed on the second PCB, electrically connected to the RF transceiver, and configured to receive a signal, a first switching circuit disposed on the first PCB and connected to the first RFFE module, and a second switching circuit disposed on the second PCB and connected to the second RFFE module. The first switching circuit may be configured to selectively connect the first RFFE module to the first antenna or the second antenna. The second switching circuit may be configured to selectively connect the second RFFE module to the first antenna or the second antenna.

According to an example embodiment, a portable communication device may comprise: a plurality of antennas including a first antenna and a second antenna configured to transmit and/or receive a signal corresponding to a designated frequency band, an RF transceiver, a plurality of RFFE modules comprising circuitry including a first RFFE module electrically connected to the RF transceiver and configured to transmit and/or receive the signal, and a second RFFE module configured to receive the signal, and a plurality of switches including a first switch and a second switch. The first switch may be configured to selectively connect the first RFFE module to the first antenna or the second antenna, and the second switch may be configured to selectively connect the second RFFE module to the first antenna or the second antenna.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram of an example electronic device in a network environment according to various example embodiments.

FIGS. 2A and 2B are diagrams illustrating examples of an electronic device for antenna switching diversity (AS-DIV) according to various example embodiments.

FIG. 3 is a diagram illustrating an example of an electronic device including a matching circuit according to various example embodiments.

FIGS. 4A and 4B are diagrams illustrating examples of an electronic device including a stub circuit according to various example embodiments.

FIGS. 5A and 5B are diagrams illustrating examples of a bar-type electronic device according to various example embodiments.

FIGS. 6A and 6B are diagrams illustrating examples of components for antenna switching diversity in a bar-type electronic device according to various example embodiments.

FIGS. 7A, 7B, and 7C are diagrams illustrating examples of a foldable-type electronic device according to various example embodiments.

FIGS. 8A, 8B, and 8C are diagrams illustrating examples of components for antenna switching diversity in a foldable-type electronic device according to various example embodiments.

FIG. 9 is a diagram illustrating an example of components for antenna switching diversity in a foldable-type electronic device according to various example embodiments.

FIGS. 10A, 10B, and 10C are diagrams illustrating examples of a foldable-type electronic device according to various example embodiments.

FIGS. 11A and 11B are diagrams illustrating examples of components for antenna switching diversity in a foldable-type electronic device according to various example embodiments.

### DETAILED DESCRIPTION

Terms used in the present disclosure are used to describe various example embodiments, and may not be intended to limit the scope of the disclosure. A singular expression may include a plural expression unless the context clearly indicates otherwise. Terms used herein, including a technical or a scientific term, may have the same meaning as those generally understood by a person with ordinary skill in the art described in the present disclosure. Among the terms used in the present disclosure, terms defined in a general dictionary may be interpreted as identical or similar meaning to the contextual meaning of the relevant technology and are not interpreted as ideal or excessively formal meaning unless explicitly defined in the present disclosure. In some cases, even terms defined in the present disclosure may not be interpreted to exclude embodiments of the present disclosure.

In various embodiments of the present disclosure described below, a hardware approach will be described as an example. However, since the various embodiments of the present disclosure include technology that uses both hardware and software, the various embodiments of the present disclosure do not exclude a software-based approach.

Terms referring to a component of an electronic device (e.g., a communication module, a wireless communication module, a substrate, a print circuit board (PCB), a flexible PCB (FPCB), a module, an antenna, an antenna element, a circuit, a processor, a chip, a component, or a device), terms referring to an RF-related component (e.g., a front end module (FEM), a power amplifier module (PAM), a FEM including duplexer (FEMid), a power amplifier module including duplexer (PAMid), an Low noise amplifier PAM including duplexer (LPAMid), a radio frequency front end (RFFE), or a radio frequency integrated circuit (RFIC)), terms referring to a shape of a component (e.g., a structure, a structural body, a support portion, a contact portion, or a protrusion), terms referring to a connection portion between structures (e.g., a connection portion, a contact portion, a support portion, a contact structure, a conductive member, or an assembly), and terms referring to a circuit (e.g., a PCB, an FPCB, a signal line, a feeding line, a data line, an RF signal line, an antenna line, an RF path, an RF module, an RF circuit, a splitter, a divider, a coupler, or a combiner) used in the following description are used for convenience of description. Therefore, the present disclosure is not limited to terms to be described below, and another term having an equivalent technical meaning may be used. In addition, a term such as ‘. . . unit’, ‘. . . device’, ‘. . . object’, and ‘. . . structure’, and the like used below may refer, for example, to at least one shape structure or may refer, for example, to a unit processing a function.

In the present disclosure, the term ‘greater than’ or ‘less than’ may be used to determine whether a particular condition is satisfied or fulfilled, but this is only a description to express an example and does not exclude description of ‘greater than or equal to’ or ‘less than or equal to’. A condition described as ‘greater than or equal to’ may be replaced with ‘greater than’, a condition described as ‘less than or equal to’ may be replaced with ‘less than’, and a condition described as’ greater than or equal to and less than’ may be replaced with ‘greater than and less than or equal to’. Hereinafter, ‘A’ to ‘B’ refers to at least one of elements from A (including A) to B (including B). Hereinafter, ‘C’ and/or ‘D’ may refer, for example, to including at least one of ‘C’ or ‘D’, that is, {‘C’, ‘D’, and ‘C’and ‘D’}.

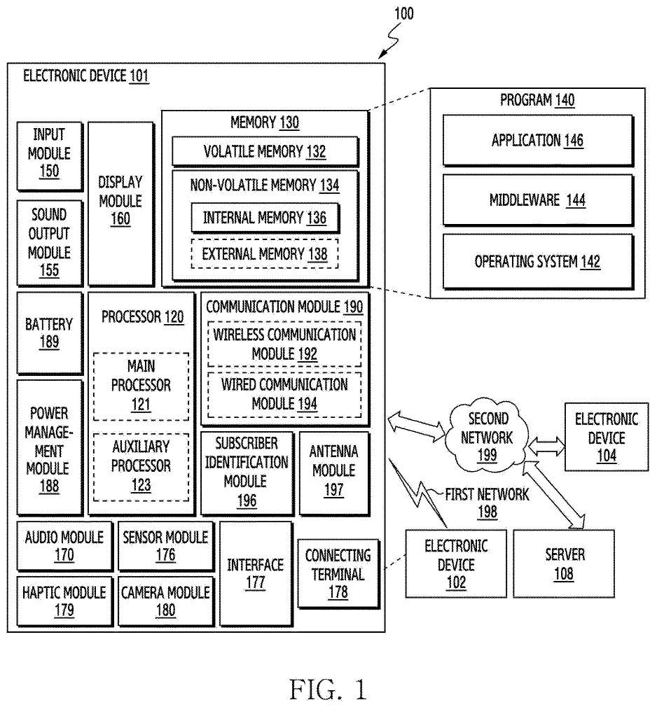

FIG. 1 is a block diagram illustrating an example electronic device 101 in a network environment 100 according to various example embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited /disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

As communication technology advances, an electronic device (e.g., the electronic device 101) may include an RFFE module supporting a plurality of RF frequency bands. For example, the electronic device 101 may transmit RF signals in two or more different frequency bands. While the number of supported frequency bands increases, antenna efficiency may decrease due to a spatial limitation of the electronic device 101. In addition, due to a grip of a user or movement of the electronic device 101, antenna performance may be difficult to be maintained continuously. In order to overcome a limit performance capable of being secured in one antenna, an antenna switching diversity (AS-DIV) technology may be used. The antenna switching diversity technology may include selection of a transmission antenna such that the electronic device 101 including two or more antennas may secure maximum performance by recognizing a field condition. For example, the electronic device 101 may receive signals through antennas, and may select a transmission antenna by analyzing quality and/or intensity of the received signals.

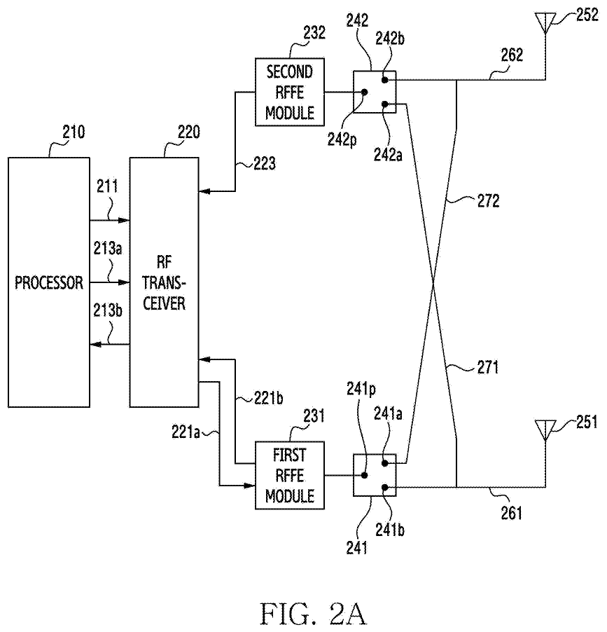

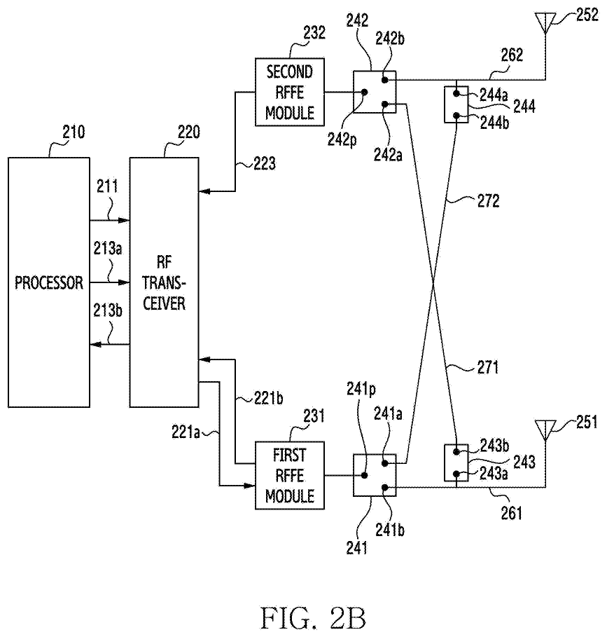

FIGS. 2A and 2B are diagrams illustrating examples of an electronic device (e.g., the electronic device 101) for antenna switching diversity (AS-DIV) according to various example embodiments.

Referring to FIG. 2A, the electronic device 101 may include a processor 210, an RF transceiver 220, a first radio frequency front end (RFFE) module (e.g., including circuitry) 231, a second RFFE module (e.g., including circuitry) 232, a first antenna 251, and a second antenna 252. The electronic device 101 may include a processor (e.g., including processing circuitry) 210. The processor 210 may include, for example, at least one of an application processor (AP) (e.g., the main processor 121 of FIG. 1) or a communication processor (CP) (e.g., the auxiliary processor 123 of FIG. 1). For example, the processor 210 may include the AP and a CP. For example, the processor 210 may include an AP. For example, the processor 210 may include a CP. The processor 210 may control the RF transceiver 220 through a control interface 211. For example, the processor 210 may generate a baseband signal. The processor 210 may control the RF transceiver 220 to process the generated baseband signal. The processor 210 may transmit a signal 213a (e.g., analog data or digital data). For example, the signal 213a may be a communication signal to be transmitted to an external electronic device (e.g., a base station, a satellite, a terminal, an electronic device 102, an electronic device 104, or a server 108). The processor 210 may control the RF transceiver 220 such that the signal is transmitted through an antenna (e.g., the first antenna 251). The processor 210 may receive a signal 213b (e.g., analog data or digital data). For example, the signal 213b may be a signal received from an external electronic device (e.g., a base station, a satellite, a terminal, an electronic device 102, an electronic device 104, or a server 108) through an antenna (e.g., the first antenna 251, or the second antenna 252). The processor 210 may control the RF transceiver 220 such that the signal 213b is received.

The processor 120 or 210 of the present disclosure may include various processing circuitry and/or multiple processors. For example, a term “processor” used in the present disclosure including claims may include various processing circuitry including at least one processor, and one or more among the at least one processor may be configured to individually and/or collectively execute various function(s) described in the present disclosure. As used in the present disclosure, in a case that “a processor”, “at least one processor”, and “one or more processors” are described as being configured to execute various functions, these terms may include, for example, situations in which one processor executes without limitation, situations in which some of the recited functions are executed by another processor(s) and other functions among the recited functions are executed, situations in which a single processor may execute all of the recited functions, and/or a combination of processors executing in a distributed manner. In addition, instructions (or program command) for various function(s) in the present disclosure may cause, when executed by a processor, an electronic device (e.g., the electronic device 101) to execute the various function(s).

The electronic device 101 may include an RF transceiver 220. For example, the RF transceiver 220 may be implemented as a single chip (e.g., an RFIC chip) or a part of a single package. The RF transceiver 220 may include components for transmission signal processing. For example, the RF transceiver 220 may provide an RF signal (e.g., a transmission signal 221a) to the first RFFE module 231. The RF transceiver 220 may include a digital to analog converter (DAC) for converting a digital signal into an analog signal. The RF transceiver 220 may include a mixer and an oscillator (e.g., a local oscillator (LO)) for up-conversion. The RF transceiver 220 may convert a baseband signal generated by the processor 210 into an RF signal. The RF transceiver 220 may include components for reception signal processing. For example, the RF transceiver 220 may receive an RF signal (e.g., a first reception signal 221b, or a second reception signal 223) from the second RFFE module 232. The RF transceiver 220 may include an analog to digital converter (ADC) for converting an analog signal into a digital signal. The RF transceiver 220 may include a mixer and an oscillator for down-conversion. The RF transceiver 220 may convert an RF signal received from an antenna 280 into a baseband signal to be processed by the processor 210. The RF transceiver 220 may include one or more transmission ports. The RF transceiver 220 may include one or more reception ports. Although not illustrated in FIG. 2A, the RF transceiver 220 may receive a feedback signal provided from a coupler connected to an antenna (e.g., the first antenna 251, or the second antenna 252). For example, the RF transceiver 220 may include a feedback receive port (FBRX) for a feedback signal. According to an embodiment, the RF transceiver 220 may control at least a portion of the first RFFE module 231 or the second RFFE module 232 through a control interface 223 (e.g., a mobile industry processor interface (MIPI)).

The electronic device 101 may include the first RFFE module 231 and the second RFFE module 232, each of which may include various circuitry. A wireless communication system is developing in a direction for supporting a higher data transmission rate to satisfy continuously increasing traffic demand of wireless data. In order to support various frequency combinations, components of a plurality of transmit (TX)/receive (RX) module, TX module, or RX module may be disposed around the RF transceiver 220. According to an embodiment, the first RFFE module 231 may indicate a module including a power amplifier (PA) for an RF signal (e.g., the transmission signal 221a) within RFFE. For example, the first RFFE module 231 may be a PAMid including a power amplifier and RF components (e.g., a duplexer, a filter, or a switch) for transmission signal processing. The first RFFE module 231 may be configured to transmit the transmission signal 221a from the RF transceiver 220 through the first antenna 251 or the second antenna 252. The transmission signal 221 from the RF transceiver 220 may be amplified by the power amplifier. The amplified transmission signal may be radiated into the air through the first antenna 251 or the second antenna 252. According to an embodiment, the first RFFE module 231 may include a module (e.g., LPAMid) that includes not only the power amplifier but also a low noise amplifier (LNA) for an RF signal (e.g., the first reception signal 221b). For example, the first RFFE module 231 may include RF components (e.g., a duplexer, a filter, or a switch) for reception signal processing. The first RFFE module 231 may provide a signal (e.g., the first reception signal 221b) received through the first antenna 251 or the second antenna 252 to the RF transceiver 220. According to an embodiment, the second RFFE module 232 may indicate a module including an LNA for an RF signal (e.g., the second reception signal 223) within RFFE. For example, the second RFFE module 232 may be a reception module including RF components (e.g., a duplexer, a filter, or a switch) for reception signal processing. The second RFFE module 232 may be configured to transmit a signal received through the first antenna 251 or the second antenna 252 to the RF transceiver 220.

The antenna switching diversity technology may refer, for example, to a technology of adaptively selecting an antenna for transmission of a signal among a plurality of antennas (e.g., the first antenna 251, or the second antenna 252). For example, the electronic device 101 may change an antenna for transmission of a signal, due to environmental factors such as a field condition or a grip state of a user. The electronic device 101 may include a first switching circuit 241 and a second switching circuit 242 for the antenna switching diversity technology. The first switching circuit 241 may be connected to the first RFFE module 231. The first switching circuit 241 may receive a transmission signal from the first RFFE module 231 or may transmit a reception signal to the first RFFE module 231. The second switching circuit 242 may be connected to the second RFFE module 232. The second switching circuit 242 may transmit a reception signal to the second RFFE module 232. In an embodiment, the first switching circuit 241 and the second switching circuit 242 of the electronic device 101 may operate in a first connection mode or a second connection mode.

According to an embodiment, in the first connection mode, the first switching circuit 241 may be configured to electrically connect the first RFFE module 231 to the first antenna 251. In the first connection mode, the second switching circuit 242 may be configured to electrically connect the second RFFE module 232 to the second antenna 252. While the first RFFE module 231 is electrically connected to the first antenna 251, the second RFFE module 232 may be electrically connected to the second antenna 252. For example, the electronic device 101 may transmit a transmission signal through the first antenna 251, in the first connection mode. For example, the electronic device 101 may receive a reception signal through the first antenna 251, in the first connection mode. For example, the electronic device 101 may receive a reception signal through the second antenna 252, in the first connection mode.

According to an embodiment, in the second connection mode, the first switching circuit 241 may be configured to electrically connect the second RFFE module 232 to the first antenna 251. In the second connection mode, the second switching circuit 242 may be configured to electrically connect the first RFFE module 231 to the second antenna 252. While the first RFFE module 231 is electrically connected to the second antenna 252, the second RFFE module 232 may be electrically connected to the first antenna 251. For example, the electronic device 101 may transmit a transmission signal through the second antenna 252, in the second connection mode. For example, the electronic device 101 may receive a reception signal through the second antenna 252, in the second connection mode. For example, the electronic device 101 may receive a reception signal through the first antenna 251, in the second connection mode.

According to an embodiment, the first switching circuit 241 may be configured to selectively connect the first RFFE module 231 to the first antenna 251 in the first connection mode or to the second antenna 252 in the second connection mode. The first antenna 251 may be connected to the first switching circuit 241 through a first path 261. The second antenna 252 may be connected to the first switching circuit 241 through a second wiring 272. For example, the first switching circuit 241 may include a single pole n throw (SPnT) switch. As an example, the first switching circuit 241 may include a single pole double throw (SPDT) switch. For example, the first switching circuit 241 may include one pole 241p, a first throw 241a, and a second throw 241b. The pole 241p may be connected to the first RFFE module 231. The first throw 241a may be electrically connected to the second antenna 252. The second throw 241b may be electrically connected to the first antenna 251.

According to an embodiment, the second switching circuit 242 may be configured to selectively connect the second RFFE module 232 to the second antenna 252 in the first connection mode or to the first antenna 251 in the second connection mode. The second antenna 252 may be connected to the second switching circuit 242 through a second path 262. The first antenna 251 may be connected to the second switching circuit 242 through a first wiring 271. For example, the second switching circuit 242 may include an SPnT switch. As an example, the second switching circuit 242 may include an SPDT switch. For example, the second switching circuit 242 may include one pole 242p, a first throw 242a, and a second throw 242b. The pole 242p may be connected to the second RFFE module 232. The first throw 242a may be electrically connected to the first antenna 251. The second throw 242b may be electrically connected to the second antenna 252.

Due to a characteristic of an RF signal, a loss may occur due to wiring. In order to reduce a loss of a feeding line, an RFFE module may be disposed close to an antenna. For example, the first RFFE module 231 may be disposed close to the first antenna 251. For example, the second RFFE module 232 may be disposed close to the second antenna 252. If the first switching circuit 241 and the second switching circuit 242 are implemented as one switch (e.g., a DPDT switch), a position of the second RFFE module 232 may be limited due to a position of the first RFFE module 231. Accordingly, a wiring length from the second RFFE module 232 to the second antenna 252 becomes long, and thus a loss of a feeding line may increase. Therefore, the electronic device 101 may individually include the first switching circuit 241 for the first RFFE module 231 and the second switching circuit 242 for the second RFFE module 232. As the first switching circuit 241 connecting the first RFFE module 231 and antennas (e.g., the first antenna 251, or the second antenna 252) and the second switching circuit 242 connecting the second RFFE module 232 and antennas (e.g., the first antenna 251, the second antenna 252) are implemented separately, the second RFFE module 232 may be disposed closer to the second antenna 252. Due to a low path loss, in the first connection mode, transmission/reception performance according to the first antenna 251 and reception performance according to the second antenna 252 may be improved.

Hereinafter, in describing various example embodiments of the present disclosure, it is described that the first RFFE module 231 includes a transmission/reception module for transmission signal processing and reception signal processing, and the second RFFE module 232 includes a reception module for reception signal processing, but the present disclosure is not limited thereto. The description of the module is merely an example, and a type of the module is not limited. If switching circuits connected to antennas for antenna switching diversity are connected to a module and another module, which respectively include a transmission path, it may be understood as an embodiment of the present disclosure. For example, the first RFFE module 231 and/or the second RFFE module 232 may be a module (e.g., a FEMid) connected to a transmission path including a power amplifier and a reception path including a low noise amplifier.

Referring to FIG. 2B, the electronic device 101 may include a processor (e.g., including processing circuitry) 210, an RF transceiver 220, a first RFFE module (e.g., including circuitry) 231, a second RFFE module (e.g., including circuitry) 232, a first antenna 251, and a second antenna 252. The electronic device 101 may include a first switching circuit 241 and a second switching circuit 242 for antenna switching diversity. The same reference numerals may denote the same description.

According to an embodiment, in the first connection mode, the first switching circuit 241 may be configured to electrically connect the first RFFE module 231 to the first antenna 251. In the first connection mode, the second switching circuit 242 may be configured to electrically connect the second RFFE module 232 to the second antenna 252.

According to an embodiment, for a transmission path in the second connection mode, a wiring may be disposed between the second switching circuit 242 and the first antenna 251. For example, a wiring (e.g., the second wiring 272) for connection with the second switching circuit 242 may be disposed in a path (e.g., the first path 261) between the first switching circuit 241 and the first antenna 251. The wiring may act as an impedance (e.g., stub) while the first RFFE module 231 is electrically connected to the first antenna 251 through the first switching circuit 241. According to an embodiment, the electronic device 101 may include a third switching circuit 243 such that an impedance mismatch due to the wiring does not occur in the first connection mode. The third switching circuit 243 may be configured to electrically disconnect the second switching circuit 242 and the first antenna 251 in the first connection mode. The third switching circuit 243 may be configured to electrically connect the second switching circuit 242 and the first antenna 251 in the second connection mode. The third switching circuit 243 may be configured to selectively electrically connect or not connect the second switching circuit 242 to a path (e.g., the first path 261) of the first switching circuit 241 and the first antenna 251. For example, the third switching circuit 243 may include a single pole single throw (SPST) switch. The third switching circuit 243 may include, for example, a pole 243a and a throw 243b. The pole 243a may be connected to the path (e.g., the first path 261). The throw 243b may be connected to the second switching circuit 242.

According to an embodiment, for a transmission path in the second connection mode, a wiring may be disposed between the first switching circuit 241 and the second antenna 252. For example, a wiring (e.g., the second wiring 272) for connection to the first switching circuit 241 may be disposed in a path (e.g., the second path 262) between the second switching circuit 242 and the second antenna 252. The wiring (e.g., the second wiring 272) may act as an impedance (e.g., stub) while the second RFFE module 232 is electrically connected to the second antenna 252 through the second switching circuit 242. According to an embodiment, the electronic device 101 may include a fourth switching circuit 244 such that an impedance mismatch due to the wiring does not occur in the first connection mode. The fourth switching circuit 244 may be configured to electrically disconnect the first switching circuit 241 and the second antenna 252 in the first connection mode. The fourth switching circuit 244 may be configured to electrically connect the first switching circuit 241 and the second antenna 252 in the second connection mode. The fourth switching circuit 244 may be configured to selectively connect or not connect the first switching circuit 241 to a path (e.g., the second path 262) of the second switching circuit 242 and the second antenna 252. For example, the fourth switching circuit 244 may include an SPST switch. The fourth switching circuit 244 may include, for example, a pole 244a and a throw 244b. The pole 244a may be connected to the path (e.g., the second path 262). The throw 244b may be connected to the first switching circuit 241.

In the present disclosure, a first connection mode and a second connection mode may be defined to describe operations of the electronic device 101 (e.g., the processor 210, or the RF transceiver 220) according to antenna switching diversity. The first connection mode indicates a state in which the first RFFE module 231 of the electronic device 101 is connected to the first antenna 251 through the first switching circuit 241 and the second RFFE module 232 of the electronic device 101 is connected to the second antenna 252 through the second switching circuit 242. In that the first RFFE module 231 is disposed to be closer to the first antenna 251 than the second antenna 252 and the second RFFE module 232 is disposed to be closer to the second antenna 252 than the first antenna 251, the first connection mode may be referred to as a default mode, a preferred mode, a default state, a preferred state, an initial state, an initial mode, a basic mode, and/or a technical term equivalent thereto. In terms of a diversity operation, the second connection mode may be referred to as a diversity mode, a switching mode, a switching state, a change state, a change mode, a diversity state, and/or a technical term equivalent thereto.

The electronic device 101 (e.g., the processor 210, or the RF transceiver 220) may control the first switching circuit 241 and the second switching circuit 242. The electronic device 101 (e.g., the processor 210, or the RF transceiver 220) may control the third switching circuit 243 and the fourth switching circuit 244. For example, the processor 210 may control the first switching circuit 241 to electrically connect the first RFFE module 231 and the first antenna 251 in the first connection mode. The processor 210 may control the second switching circuit 242 to electrically connect the second RFFE module 232 and the second antenna 252 in the first connection mode. Hereinafter, a connection operation of the first switching circuit 241 or a connection operation of the second switching circuit 242 may be understood as control by the processor 210 and/or the RF transceiver 220. The second connection mode indicates a state in which the first RFFE module 231 of the electronic device 101 is connected to the second antenna 252 through the first switching circuit 241 and the second RFFE module 232 of the electronic device 101 is connected to the first antenna 251 through the second switching circuit 242. For example, the processor 210 may control the first switching circuit 241 to electrically connect the first RFFE module 231 and the second antenna 252 in the second connection mode. The processor 210 may control the second switching circuit 242 to electrically connect the second RFFE module 232 and the first antenna 251 in the second connection mode. Hereinafter, a connection operation of the first switching circuit 241 or a connection operation of the second switching circuit 242 may be understood as control by the processor 210 and/or the RF transceiver 220.

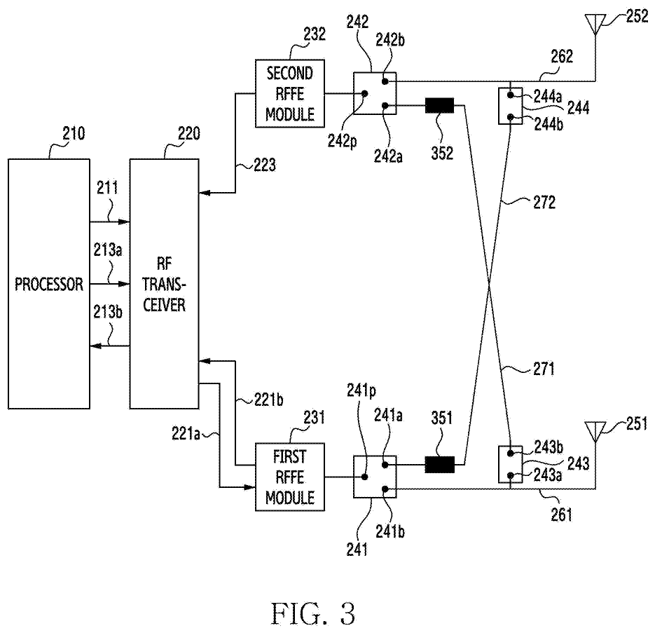

FIG. 3 is a diagram illustrating an example of an electronic device (e.g., the electronic device 101) including a matching circuit according to various example embodiments. The electronic device 101 may include a processor (e.g., including processing circuitry) 210, an RF transceiver 220, a first RFFE module (e.g., including circuitry) 231, a second RFFE module (e.g., including circuitry) 232, a first antenna 251, and a second antenna 252. For antenna switching diversity, the electronic device 101 may include a first switching circuit 241, a second switching circuit 242, a third switching circuit 243, and a fourth switching circuit 244. The same reference numerals may denote the same description.

Referring to FIG. 3, the electronic device 101 may include a first matching circuit 351 and/or a second matching circuit 352. According to an embodiment, the first matching circuit 351 may be connected to the first switching circuit 241. In the first connection mode, the first switching circuit 241 may be configured to electrically connect the first RFFE module 231 to the first antenna 251. In the second connection mode, the first switching circuit 241 may be configured to electrically connect the first RFFE module 231 to the second antenna 252. A first throw 241a of the first switching circuit 241 may be connected to the first matching circuit 351. While a pole 241p of the first switching circuit 241 is connected to the first throw 241a connected to the second antenna 252, the first matching circuit 351 may be used for impedance matching for the second antenna 252. For example, the first matching circuit 351 may include at least one passive element (e.g., an inductor, or a capacitor). For example, the first matching circuit 351 may include an element for providing variable impedance. The first matching circuit 351 may be used for impedance matching of a transmission signal transmitted through the first RFFE module 231 and the first antenna 251. A value of an element of the first matching circuit 351 may be configured to provide the impedance matching.

According to an embodiment, the second matching circuit 352 may be connected to the second switching circuit 242. In the first connection mode, the second switching circuit 242 may be configured to electrically connect the second RFFE module 232 to the second antenna 252. In the second connection mode, the second switching circuit 242 may be configured to electrically connect the second RFFE module 232 to the first antenna 251. A first throw 242a of the second switching circuit 242 may be connected to the second matching circuit 352. While a pole 242p of the second switching circuit 242 is connected to the first throw 242a connected to the first antenna 251, the second matching circuit 352 may be used for impedance matching for the first antenna 251. For example, the second matching circuit 352 may include at least one passive element (e.g., an inductor, or a capacitor). For example, the second matching circuit 352 may include an element for providing variable impedance. The second matching circuit 352 may be used for impedance matching of a reception signal received through the second RFFE module 232 and the second antenna 252. A value of an element of the second matching circuit 352 may be configured to provide the impedance matching.

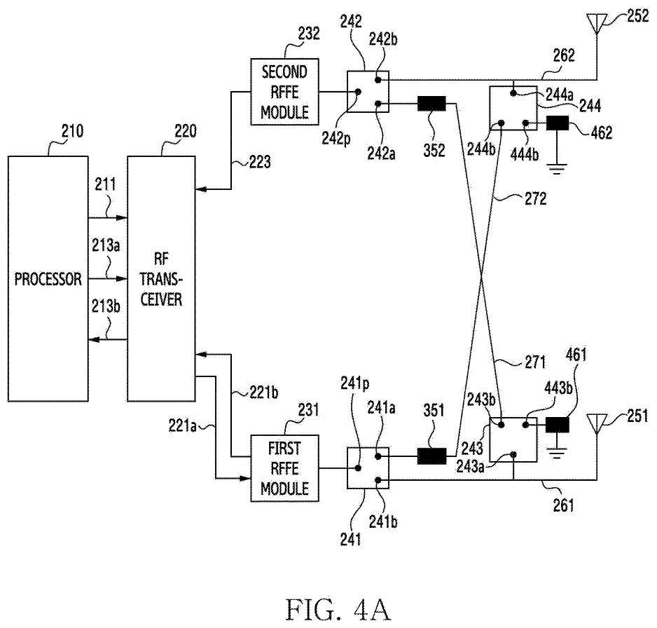

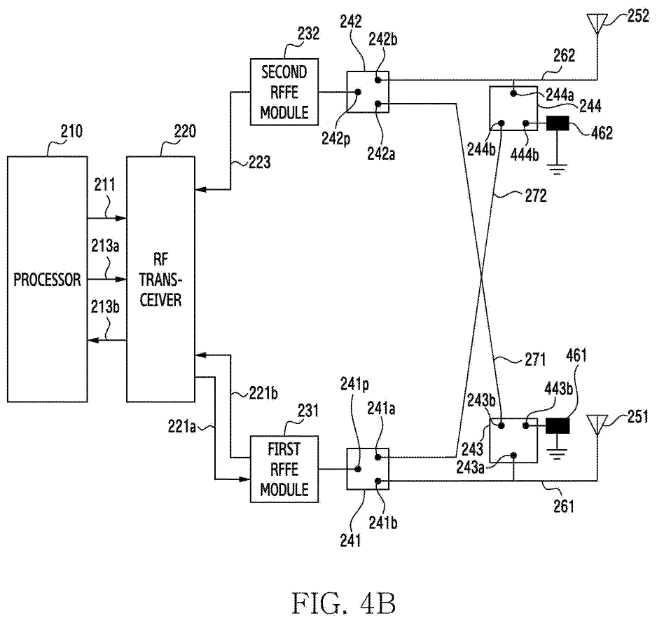

FIGS. 4A and 4B are diagrams illustrating examples of an electronic device (e.g., the electronic device 101) including a stub circuit according to various example embodiments. The electronic device 101 may include a processor (e.g., including processing circuitry) 210, an RF transceiver 220, a first RFFE module (e.g., including circuitry) 231, a second RFFE module (e.g., including circuitry) 232, a first antenna 251, and a second antenna 252. In an embodiment, the electronic device 101 may include a first switching circuit 241, a second switching circuit 242, a third switching circuit 243, and/or a fourth switching circuit 244, for antenna switching diversity. The same reference numerals may denote the same description.

Referring to FIG. 4A, the electronic device 101 may include a first stub circuit 461 and/or a second stub circuit 462. The third switching circuit 243 and the fourth switching circuit 244 may be used for impedance matching, in addition to preventing and/or reducing an impedance mismatch due to a stub in a first connection mode of antenna switching diversity.

In an embodiment, the first stub circuit 461 may be connected to the third switching circuit 243. For example, the third switching circuit 243 may include an SPDT switch. The third switching circuit 243 may include a pole 243a, a throw 243b, and a matching throw 443b. The pole 243a may be connected to a path (e.g., a first path 261 connecting a first throw 241a of the first switching circuit 241 and the first antenna 251) of the first antenna 251. The throw 243b may be connected to the second switching circuit 242 through the second matching circuit 352. The matching throw 443b may be connected to the first stub circuit 461. The first stub circuit 461 may be connected to ground. For example, while a pole 241p of the first switching circuit 241 is connected to a second throw 242b connected to the first antenna 251, the pole 243a of the third switching circuit 243 may be connected to the matching throw 443b. The first path 261 may be connected to the first stub circuit 461. The first stub circuit 461 may be used for impedance matching (e.g., shunt matching) for the first antenna 251. For example, the first stub circuit 461 may include at least one passive element (e.g., an inductor, or a capacitor). For example, the first stub circuit 461 may include an element for providing variable impedance. The first stub circuit 461 may be used for impedance matching of a transmission signal transmitted through the first RFFE module 231 and the first antenna 251. A value of an element of the first stub circuit 461 may be configured to provide the impedance matching. Through the first stub circuit 461, impedance matching for signal transmission of the first antenna 251 may be performed. For example, through the first stub circuit 461, impedance matching according to a wiring to the first antenna 251, a load of the first antenna 251, and/or an internal circuit component may be optimized.

In an embodiment, the second stub circuit 462 may be connected to the fourth switching circuit 244. For example, the fourth switching circuit 244 may include an SPDT switch. The fourth switching circuit 244 may include a pole 244a, a throw 244b, and a matching throw 444b. The pole 244a may be connected to a path (e.g., a second path 262 connecting the second throw 242b of the second switching circuit 242 and the second antenna 252) of the second antenna 252. The throw 244b may be connected to the first switching circuit 241 through the first matching circuit 351. The matching throw 444b may be connected to the second stub circuit 462. The second stub circuit 462 may be connected to ground. For example, while a pole 242p of the second switching circuit 242 is connected to the second throw 242b connected to the second antenna 252, the pole 244a of the fourth switching circuit 244 may be connected to the matching throw 444b. The second path 262 may be connected to the second stub circuit 462. The second stub circuit 462 may be used for impedance matching (e.g., shunt matching) for the second antenna 252. For example, the second stub circuit 462 may include at least one passive element (e.g., an inductor, or a capacitor). For example, the second stub circuit 462 may include an element for providing variable impedance. In an embodiment, the second stub circuit 462 may be used for impedance matching of a reception signal received through the second RFFE module 232 and the second antenna 252. A value of an element of the second stub circuit 462 may be configured to provide the impedance matching. Through the second stub circuit 462, impedance matching for signal reception of the second antenna 252 may be performed. For example, through the second stub circuit 462, impedance matching according to a path (e.g., the second path 262) to the second antenna 252, a load of the second antenna 252, and/or an internal circuit component may be optimized.

In FIG. 4A, an example of an electronic device including all of the first matching circuit 351 and the second matching circuit 352 for impedance matching in the second connection mode and the first stub circuit 461 and the second stub circuit 462 for impedance matching in the first connection mode has been described, but the present disclosure is not limited thereto. For example, as illustrated in FIG. 4B, the first matching circuit 351 and the second matching circuit 352 may be omitted. Without the first matching circuit 351 and the second matching circuit 352, the first stub circuit 461 connected to the third switching circuit 243 and/or the second stub circuit 462 connected to the fourth switching circuit 244 may be used for impedance matching in the first connection mode.

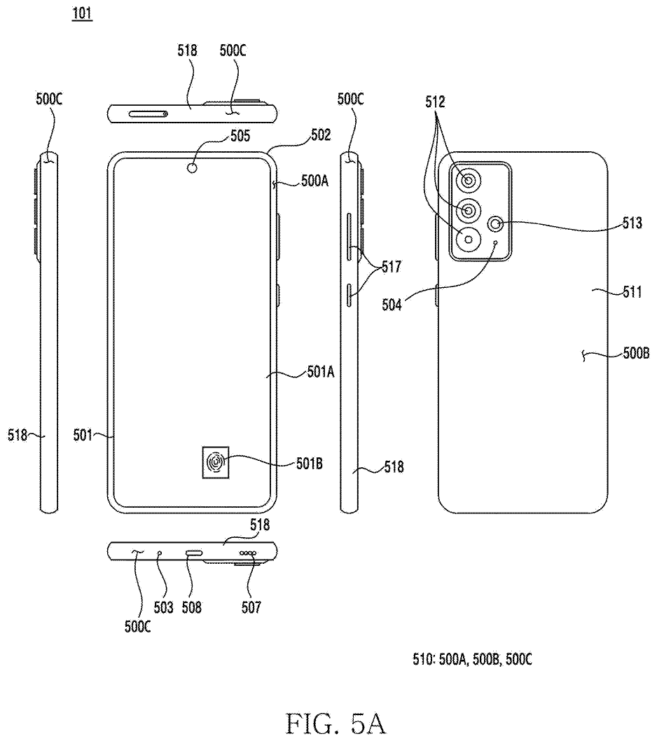

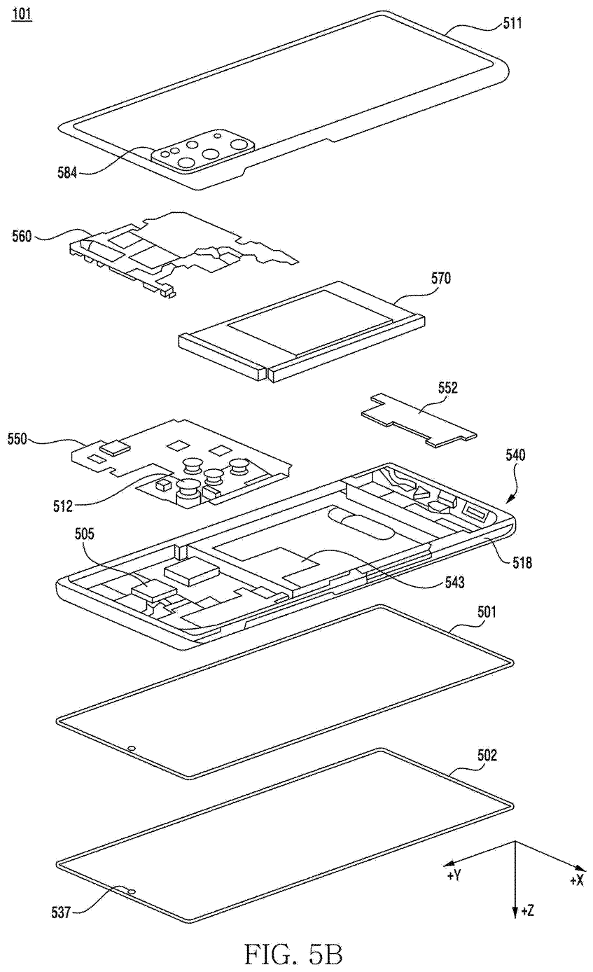

FIGS. 5A and 5B are diagrams illustrating examples of a bar-type electronic device (e.g., the electronic device 101) according to various example embodiments.

Referring to FIG. 5A, for example, the electronic device 101 may include a housing 510 forming an exterior of the electronic device 101. For example, the housing 510 may include a front surface 500A, a rear surface 500B, and a lateral surface 500C surrounding a space between the front surface 500A and the rear surface 500B. For example, the housing 510 may refer to a structure forming at least a portion of the front surface 500A, the rear surface 500B, and/or the lateral surface 500C.

For example, the electronic device 101 may include a substantially transparent front plate 502. For example, the front plate 502 may form at least a portion of the front surface 500A. For example, the front plate 502 may include a glass plate or polymer plate, including various coating layers, but is not limited thereto.

For example, the electronic device 101 may include a substantially opaque rear plate 511. For example, the rear plate 511 may form at least a portion of the rear surface 500B. For example, the rear plate 511 may be formed of coated or colored glass, ceramic, polymer, metal (e.g., aluminum, stainless steel (STS), or magnesium), or a combination of at least two of the above materials.

For example, the electronic device 101 may include a side bezel structure (or a side member) 518. For example, the side bezel structure 518 may be coupled with the front plate 502 and/or the rear plate 511 and form at least a portion of the lateral surface 500C of the electronic device 101. For example, the side bezel structure 518 may form all of the lateral surface 500C of the electronic device 101, and for another example, the side bezel structure 518 may form the lateral surface 500C of the electronic device 101 together with the front plate 502 and/or the rear plate 511.

Unlike the illustrated embodiment, in a case that the lateral surface 500C of the electronic device 101 is partially formed by the front plate 502 and/or the rear plate 511, the front plate 502 and/or the rear plate 511 may include an extended portion that is bent toward the rear plate 511 and/or the front plate 502 at a periphery thereof and seamlessly extends. The extended portion of the front plate 502 and/or the rear plate 511 may be located, for example, at both ends of a long edge of the electronic device 101, but is not limited by the above-described example.

For example, the side bezel structure 518 may include metal and/or polymer. For example, the rear plate 511 and the side bezel structure 518 may be integrally formed and may include the same material (e.g., a metal material such as aluminum), but are not limited thereto. For example, the rear plate 511 and the side bezel structure 518 may be formed as separate configurations and/or may include different materials.

For example, the electronic device 101 may include at least one of a display 501 (e.g., the display module 160 of FIG. 1), audio modules 503, 504, and 507 (e.g., the audio module 170 of FIG. 1), a sensor module (not illustrated) (e.g., the sensor module 176 of FIG. 1), camera modules 505 and 212 (e.g., the camera module 180 of FIG. 1), an key input device 517 (e.g., the input module 150 of FIG. 1), a light-emitting element (not illustrated), and/or a connector hole 508. For example, the electronic device 101 may omit at least one (e.g., the input device 517 or the light-emitting element (not illustrated)) of the components or may additionally include another component.

For example, the display 501 may be visible through a substantial portion of the front plate 502. For example, at least a portion of the display 501 may be visible through the front plate 502 forming the front surface 500A. For example, the display 501 may be disposed on a rear side of the front plate 502.

For example, an outer shape of the display 501 may be formed to be substantially the same as an outer shape of the front plate 502 adjacent to the display 501. For example, in order to expand an area in which the display 501 is visible, an interval between an outer edge of the display 501 and an outer edge of the front plate 502 may be formed to be substantially the same.

For example, the display 501 (or the front surface 500A of the electronic device 101) may include a screen display area 501A. For example, the display 501 may provide visual information to a user through the screen display area 501A. In the illustrated embodiment, when the front surface 500A is viewed from the front, the screen display area 501A is illustrated as being spaced apart from an outer edge of the front surface 500A and located inside the front surface 500A, but is not limited thereto. In an embodiment, when the front surface 500A is viewed from the front, at least a portion of a periphery of the screen display area 501A may substantially coincide with a periphery of the front surface 500A (or the front plate 502).

For example, the screen display area 501A may include a sensing area 501B configured to obtain biometric information of a user. Herein, a meaning of “the screen display area 501A includes the sensing area 501B” may be understood as that at least a portion of the sensing area 501B may be overlapped with the screen display area 501A. For example, the sensing area 501B may refer to an area capable of displaying visual information by the display 501 as in other areas of the screen display area 501A, and additionally capable of obtaining biometric information (e.g., a fingerprint) of a user. For example, the sensing area 501B may be formed in the key input device 517.

For example, the display 501 may include an area in which a first camera 505 is located. For example, an opening may be formed in the area of the display 501, and the first camera 505 (e.g., a punch hole camera) may be at least partially disposed in the opening to face the front surface 500A. In this case, the screen display area 501A may surround at least a portion of a periphery of the opening. For example, the first camera 505 (e.g., an under display camera (UDC)) may be disposed under the display 501 to overlap with the area of the display 501. In this case, the display 501 may provide visual information to a user through the area, and additionally, the first camera 505 may obtain an image corresponding to a direction facing the front surface 500A through the area of the display 501.

For example, the display 501 may be coupled with or disposed adjacent to a touch sensing circuit, a pressure sensor capable of measuring a strength (pressure) of a touch, and/or a digitizer for detecting a magnetic-type stylus pen.

For example, the audio modules 503, 504, and 507 may include microphone holes 503 and 504 and a speaker hole 507.

For example, the microphone holes 503 and 504 may include a first microphone hole 503 formed in a partial area of the lateral surface 500C and a second microphone hole 504 formed in a partial area of the rear surface 500B. A microphone (not illustrated) for obtaining an external sound may be disposed inside the microphone holes 503 and 504. The microphone may include a plurality of microphones to detect a direction of sound.

For example, the second microphone hole 504 formed in a partial area of the rear surface 500B may be disposed adjacent to the camera modules 505 and 212. For example, the second microphone hole 504 may obtain sound according to an operation of the camera modules 505 and 212. However, the disclosure is not limited thereto.

The speaker hole 507 may include an external speaker hole 507 and a receiver hole for a call (not illustrated). The external speaker hole 507 may be formed in a portion of the lateral surface 500C of the electronic device 101. For example, the external speaker hole 507 may be implemented as one hole with the microphone hole 503. Although not illustrated, the receiver hole for a call (not illustrated) may be formed in another portion of the lateral surface 500C. For example, the receiver hole for a call may be formed on an opposite side of the external speaker hole 507 on the lateral surface 500C. For example, based on the illustration of FIG. 5A, the external speaker hole 507 may be formed on the lateral surface 500C corresponding to a lower end portion of the electronic device 101, and the receiver hole for a call may be formed on the lateral surface 500C corresponding to an upper end portion of the electronic device 101. However, the disclosure is not limited thereto, and for example, the receiver hole for a call may be formed at a position other than the lateral surface 500C. For example, the receiver hole for a call may be formed by a separated space between the front plate 502 (or the display 501) and the side bezel structure 518.

For example, the electronic device 101 may include at least one speaker (not illustrated) configured to output sound to an outside of the housing through the external speaker hole 507 and/or the receiver hole for a call (not illustrated). For example, the speaker may include a piezo speaker configured to output audio by vibrating a diaphragm in the speaker using a piezoelectric element. However, the disclosure is not limited thereto.

For example, a sensor module (not illustrated) may generate an electrical signal or a data value corresponding to an internal operating state of the electronic device 101 or an external environmental state. For example, the sensor module may include at least one of a proximity sensor, a heart rate monitor (HRM) sensor, a fingerprint sensor, a gesture sensor, a gyro sensor, a pressure sensor, a magnetic sensor, an acceleration sensor, a grip sensor, a color sensor, an infrared (IR) sensor, a biometric sensor, a temperature sensor, a humidity sensor, or an illuminance sensor.

For example, the camera modules 505 and 512 may include a first camera 505 disposed to face the front surface 500A of the electronic device 101 and a second camera 512 disposed to face the rear surface 500B.

For example, the second camera 512 may include a plurality of cameras (e.g., a dual camera, a triple camera, or a quad camera). However, the second camera 512 is not necessarily limited to including the plurality of cameras and may include one camera.

For example, the first camera 505 and the second camera 512 may include one or more lenses, an image sensor, and/or an image signal processor.

For example, the electronic device 101 may include a flash 513 disposed to face the rear surface 500B. For example, the flash 513 may include, for example, a light-emitting diode or a xenon lamp. For example, two or more lenses (infrared camera, wide-angle and telephoto lens) and image sensors may be disposed on a surface of the electronic device 101.

For example, the key input device 517 may be disposed on the lateral surface 500C of the electronic device 101. For example, the electronic device 101 may not include a portion or all of the key input device 517, and the key input device 517 not included may be implemented in another form such as a soft key on the display 501.

For example, the connector hole 508 may be formed in the lateral surface 500C of the electronic device 101 to accommodate a connector of an external device. A connection terminal (e.g., the connecting terminal 178 of FIG. 1) electrically connected to the connector of the external device may be disposed in the connector hole 508. For example, the electronic device 101 may include an interface module (e.g., the interface 177 of FIG. 1) for processing an electrical signal transmitted and received through the connection terminal.

For example, the electronic device 101 may include a light-emitting element (not illustrated). For example, the light-emitting element (not illustrated) may be disposed on the front surface 500A of the housing. The light-emitting element (not illustrated) may provide state information of the electronic device 101 in an optical form. For example, the light-emitting element (not illustrated) may provide a light source linked with an operation of the first camera 505. For example, the light-emitting element (not illustrated) may include an LED, an IR LED, and/or a xenon lamp.

FIG. 5B is an exploded perspective view of the electronic device 101 illustrated in FIG. 5A according to various example embodiments. Hereinafter, a duplicated description with respect to a configuration having the same reference numeral as the above-described configuration may not be repeated.

Referring to FIG. 5B, for example, the electronic device 101 may include a display 501, a front plate 502, a rear plate 511, a frame structure 540, a first printed circuit board 550, a second printed circuit board 552, a cover structure 560, and a battery 570 (e.g., the battery 189 of FIG. 1).

For example, the frame structure 540 may include a side bezel structure 518 forming an exterior (e.g., the lateral surface 500C of FIG. 5A) of the electronic device 101 and a support structure 543 extending inward from the side bezel structure 518. For example, the frame structure 540 may be disposed between the display 501 and the rear plate 511. For example, the side bezel structure 518 of the frame structure 540 may surround a space between the rear plate 511 and the front plate 502 (and/or the display 501), and the support structure 543 of the frame structure 540 may extend from the side bezel structure 518 within the space.

For example, the frame structure 540 may support or accommodate other components included in the electronic device 101. For example, the display 501 may be disposed on a surface of the frame structure 540 facing a direction (e.g., the +z direction), and the display 501 may be supported by the support structure 543 of the frame structure 540. For example, the first printed circuit board 550, the second printed circuit board 552, the battery 570, and the second camera 512 may be disposed on another surface of the frame structure 540 facing an opposite direction (e.g., the −z direction) to the direction. The first printed circuit board 550, the second printed circuit board 552, the battery 570, and the second camera 512 may be seated in a recess defined by the side bezel structure 518 and/or the support structure 543 of the frame structure 540.

For example, the first printed circuit board 550, the second printed circuit board 552, and the battery 570 may be respectively coupled to the frame structure 540. For example, the first printed circuit board 550 and the second printed circuit board 552 may be fixedly disposed at the frame structure 540 through a coupling member such as a screw. For example, the battery 570 may be fixedly disposed at the frame structure 540 through an adhesive member (e.g., a double-sided tape). However, the disclosure is not limited thereto.

For example, the cover structure 560 may be disposed between the first printed circuit board 550 and the rear plate 511. For example, the cover structure 560 may be disposed on the first printed circuit board 550. For example, the cover structure 560 may be disposed on a surface of the first printed circuit board 550 facing the −z direction.

For example, the cover structure 560 may be at least partially overlapped with the first printed circuit board 550 with respect to the z-axis. For example, the cover structure 560 may cover at least a portion of the first printed circuit board 550. Through this, the cover structure 560 may protect the first printed circuit board 550 from a physical impact or prevent/reduce separation of a connector coupled to the first printed circuit board 550.

For example, the cover structure 560 may be fixedly disposed on the first printed circuit board 550 through a coupling member (e.g., a screw), or may be coupled to the frame structure 540 together with the first printed circuit board 550 through the coupling member.

For example, the display 501 may be disposed between the frame structure 540 and the front plate 502. For example, the front plate 502 may be disposed on a side (e.g., the +z direction) of the display 501, and the frame structure 540 may be disposed on another side (e.g., the −z direction).

For example, the front plate 502 may be coupled to the display 501. For example, the front plate 502 and the display 501 may be adhered to each other through an optical adhesive member (e.g., an optically clear adhesive (OCA) or an optically clear resin (OCR)) interposed therebetween.

For example, the front plate 502 may be coupled to the frame structure 540. For example, the front plate 502 may include an outer portion extending outward from the display 501 when viewed in the z-axis direction, and may be adhered to the frame structure 540 through an adhesive member (e.g., a double-sided tape) disposed between the outer portion of the front plate 502 and the frame structure 540 (e.g., the side bezel structure 518). However, the disclosure is not limited thereto.

For example, a processor (e.g., the processor 120 of FIG. 1), memory (e.g., the memory 130 of FIG. 1), and/or an interface (e.g., the interface 177 of FIG. 1) may be mounted on the first printed circuit board 550 and/or the second printed circuit board 552. The processor may include, for example, one or more of a central processing unit, an application processor, a graphics processing unit, an image signal processor, a sensor hub processor, or a communication processor. The memory may include, for example, a volatile memory (e.g., the volatile memory 132 of FIG. 1) or a non-volatile memory (e.g., the non-volatile memory 134 of FIG. 1). The interface may include, for example, a high definition multimedia interface (HDMI), a universal serial bus (USB) interface, an SD card interface, and/or an audio interface. The interface may electrically or physically connect the electronic device 101 to an external electronic device, and may include a USB connector, an SD card/multimedia card (MMC) connector, or an audio connector. For example, the first printed circuit board 550 and the second printed circuit board 552 may be operably or electrically connected to each other through a connection member (e.g., a flexible printed circuit board).

For example, the battery 570 may provide power to at least one component of the electronic device 101. For example, the battery 570 may include a rechargeable secondary battery or a fuel cell. At least a portion of the battery 570 may be disposed on substantially the same plane as the first printed circuit board 550 and/or the second printed circuit board 552.

For example, the electronic device 101 may include an antenna module (not illustrated). For example, the antenna module may be disposed between the rear plate 511 and the battery 570. The antenna module may include, for example, a near field communication (NFC) antenna, a wireless charging antenna, and/or a magnetic secure transmission (MST) antenna. The antenna module may, for example, perform near field communication with an external device or transmit and receive power wirelessly with an external device.

For example, the first camera 505 (e.g., a front camera) may be disposed on at least a portion (e.g., the support structure 543) of the frame structure 540 such that a lens receives external light through a partial area (e.g., the camera area 537) of the front plate 502 (e.g., the front surface 500A of FIG. 5A).

For example, the second camera 512 (e.g., a rear camera) may be disposed between the frame structure 540 and the rear plate 511. For example, the second camera 512 may be electrically connected to the first printed circuit board 550 through a connection member (e.g., a connector). For example, the second camera 512 may be disposed such that a lens receives external light through a camera area 584 of the rear plate 511 of the electronic device 101.

For example, the camera area 584 may be formed on a surface (e.g., the rear surface 500B of FIG. 5A) of the rear plate 511. For example, the camera area 584 may be formed to be at least partially transparent such that external light may be incident to a lens of the second camera 512. For example, at least a portion of the camera area 584 may protrude from the surface of the rear plate 511 by a predetermined height. However, the disclosure is not limited thereto, and in an embodiment, the camera area 584 may form substantially the same plane as the surface of the rear plate 511.

For example, a housing (e.g., the housing 510 of FIG. 5A) of the electronic device 101 may refer to a configuration or a structure forming at least a portion of an exterior of the electronic device 101. In this regard, at least a portion of the front plate 502, the frame structure 540, and/or the rear plate 511 forming the exterior of the electronic device 101 may be referred to as the housing 510 of the electronic device 101.

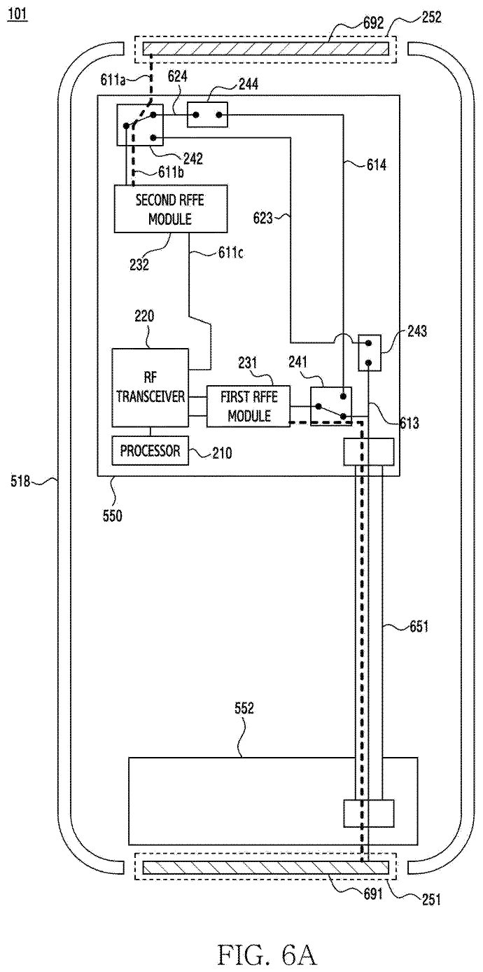

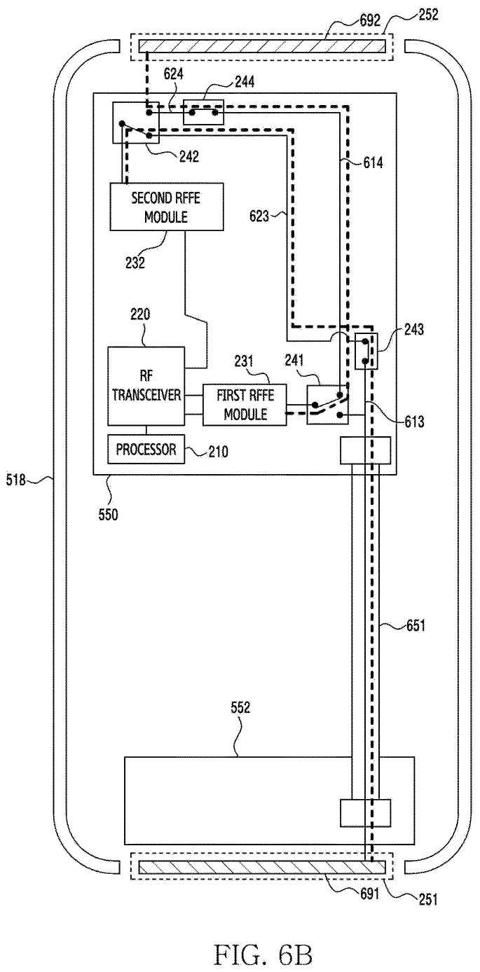

FIGS. 6A and 6B are diagrams illustrating examples of components for antenna switching diversity in a bar-type electronic device (e.g., the electronic device 101) according to various example embodiments. The structure illustrated in FIGS. 5A and 5B may be used to describe the electronic device 101. However, other components of FIGS. 5A and 5B are not interpreted as limiting FIGS. 6A and 6B.

Referring to FIGS. 6A and 6B, the electronic device 101 may include a processor 210, an RF transceiver 220, a first RFFE module 231, a second RFFE module 232, a first antenna 251, and a second antenna 252. In an embodiment, the electronic device 101 may include a plurality of switching circuits (e.g., a first switching circuit 241, a second switching circuit 242, a third switching circuit 243, and/or a fourth switching circuit 244) for antenna switching diversity. The same reference numerals may denote the same description. FIG. 6A illustrates a connection state of the plurality of switching circuits in a first connection mode. FIG. 6B illustrates a connection state of the plurality of switching circuits in a second connection mode.

The electronic device 101 may include a housing 510. The housing 510 may include a plurality of conductive portions. The plurality of conductive portions may be formed on a lateral surface of the housing 510. For example, each conductive portion may be at least a portion of a metal frame of the housing 510. For example, a conductive portion may be formed through segments that are non-conductive portions of the metal frame. Each non-conductive portion may be disposed between the conductive portions. A portion of the conductive portion may be used as an antenna radiator for transmission or reception of a signal. For example, the electronic device 101 may use a first conductive portion 691 disposed at a lower end of the electronic device 101 as the first antenna 251. For example, the electronic device 101 may use a second conductive portion 692 disposed at an upper end of the electronic device 101 as the second antenna 252. The electronic device 101 may include a first printed circuit board 550. The processor 210, the RF transceiver 220, the first RFFE module 231, the second RFFE module 232, the first switching circuit 241, the second switching circuit 242, the third switching circuit 243, and the fourth switching circuit 244 may be disposed on the first printed circuit board 550. The electronic device 101 may include a second printed circuit board 552. For example, the second printed circuit board 552 may include elements (e.g., a tuning circuit, or a tuning element) for the first conductive portion 691 corresponding to the first antenna 251. The electronic device 101 may include a connection member 651 (e.g., flexible RF cable (FRC), FPCB). The connection member 651 may be used for an electrical connection between the first printed circuit board 550 and the second printed circuit board 552. A transmission signal may be provided to the first antenna 251 through the connection member 651. The transmission signal may be transmitted to the first antenna 251 through the first RFFE module 231 and the first switching circuit 241 in the first connection mode or may be transmitted to the first antenna 251 through the second RFFE module 232, the second switching circuit 242, and the third switching circuit 243 in the second connection mode.

In an embodiment, the first RFFE module 231 may be disposed as close as possible to the first conductive portion 691 to reduce a path loss. The second RFFE module 232 may be disposed as close as possible to the second conductive portion 692 to reduce a path loss. As each RFFE module is disposed close to a corresponding antenna, the first switching circuit 241 connected to the first RFFE module 231 and the second switching circuit 242 connected to the second RFFE module 232 may be spaced apart from each other to implement an antenna switching diversity technology. As the second RFFE module 232 is located close to the second conductive portion 692 included in the second antenna 252, lengths of wirings between components on a path from the RF transceiver 220 to the second antenna 252 may vary. For example, as the second RFFE module 232 is located closer to the second antenna 252, a length of a wiring 611c between the RF transceiver 220 and the second RFFE module 232 may increase. As the second RFFE module 232 is located closer to the second antenna 252, a length of a wiring 611a between the second antenna 252 and the second switching circuit 242 and a length of a wiring 611b between the second switching circuit 242 and the second RFFE module 232 may decrease. For example, a distance between the RF transceiver 220 and the second RFFE module 232 may be longer than a distance between the second antenna 252 and the second RFFE module 232.

A wiring 613 between the first switching circuit 241 and the third switching circuit 243 may be formed. A wiring 624 between the second switching circuit 242 and the fourth switching circuit 244 may be formed. A wiring 614 between the first switching circuit 241 and the fourth switching circuit 244 may be formed. A wiring 623 between the second switching circuit 242 and the third switching circuit 243 may be formed. As the second RFFE module 232 and the second switching circuit 242 are located close to the second conductive portion 692, a length between the second RFFE module 232 and the second conductive portion 692 may be shorter than a length between the second RFFE module 232 and the first conductive portion 691.

In the first connection mode, the first switching circuit 241 may be configured to electrically connect the first RFFE module 231 to the first antenna 251. In the first connection mode, the second switching circuit 242 may be configured to electrically connect the second RFFE module 232 to the second antenna 252. In the first connection mode, the fourth switching circuit 244 may be opened. Although not illustrated in FIG. 6A, in an embodiment, the fourth switching circuit 244 may electrically connect the second switching circuit 242 and the second stub circuit 462 for impedance matching to the second antenna 252 in the first connection mode, instead of being opened. In the first connection mode, the third switching circuit 243 may be opened. Although not illustrated in FIG. 6A, in an embodiment, the third switching circuit 243 may electrically connect the first switching circuit 241 and the first stub circuit 461 for impedance matching to the first antenna 251 in the first connection mode, instead of being opened.

In the second connection mode, the first switching circuit 241 may be configured to electrically connect the first RFFE module 231 to the second antenna 252. In the second connection mode, the second switching circuit 242 may be configured to electrically connect the second RFFE module 232 to the first antenna 251. In the second connection mode, the third switching circuit 243 may be configured to electrically connect the second switching circuit 242 to the first antenna 251. In the second connection mode, the fourth switching circuit 244 may be configured to electrically connect the first switching circuit 241 to the second antenna 252.

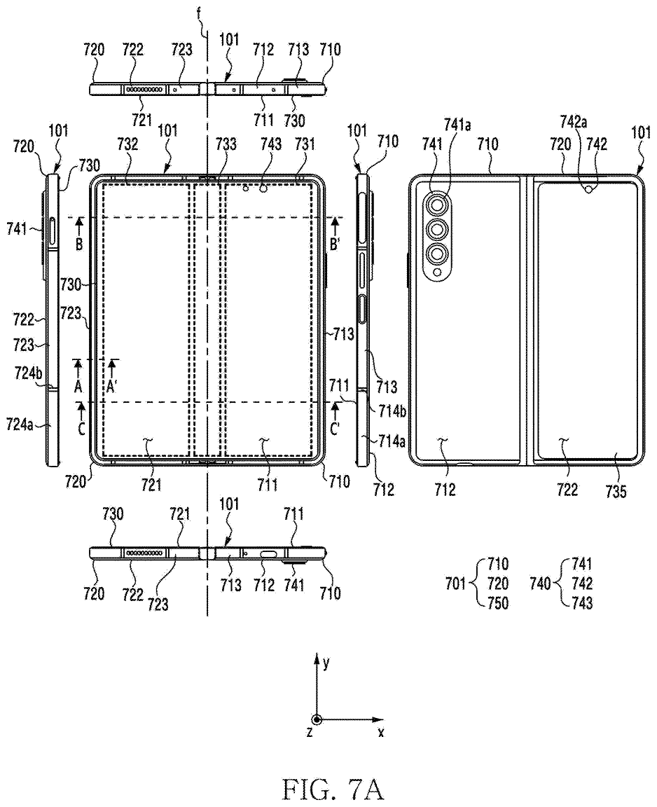

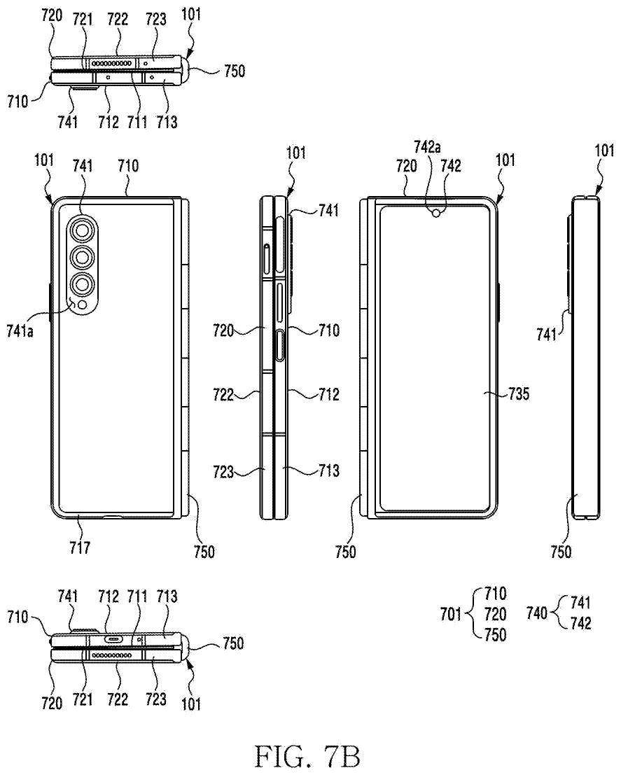

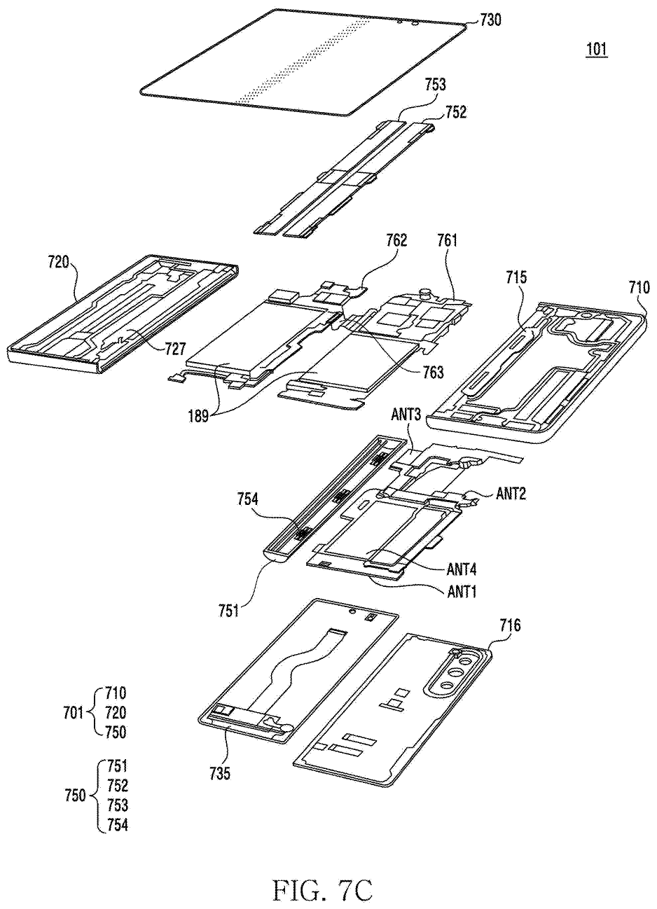

FIGS. 7A, 7B, and 7C are diagrams illustrating examples of a foldable-type electronic device (e.g., the electronic device 101) according to various example embodiments. FIG. 7A is a diagram illustrating an example of an unfolded state of an example foldable electronic device according to various example embodiments. FIG. 7B is a diagram illustrating an example of a folded state of an example foldable electronic device according to various example embodiments. FIG. 7C is an exploded perspective view of an example foldable electronic device according to various example embodiments.

Referring to FIGS. 7A, 7B, and 7C, a foldable electronic device (e.g., the electronic device 101 of FIG. 1) may include a housing 701, a flexible display 730 (e.g., the display module 160 of FIG. 1), and at least one camera 740.

For example, the housing 701 may form an exterior of the foldable electronic device 101. For example, the housing 701, which is a physical exterior of the foldable electronic device 101 exposed to an outside, may surround components disposed inside the foldable electronic device 101 and not exposed to the outside. For example, the housing 701 may include a first housing 710, a second housing 720, and a hinge structure 750.

For example, the first housing 710 may include a first surface 711, a second surface 712 opposite to the first surface 711, and a first lateral surface 713 surrounding at least a portion of the first surface 711 and the second surface 712. For example, the first surface 711 may be referred to as a front surface of the first housing 710, and the second surface 712 may be referred to as a rear surface of the first housing 710. The first lateral surface 713 may be connected to a periphery of the first surface 711 and a periphery of the second surface 712. The first surface 711, the second surface 712, and the first lateral surface 713 may form an internal space of the first housing 710. For example, at least one component may be disposed in a space surrounded by the first surface 711, the second surface 712, and the first lateral surface 713.

For example, the second housing 720 may include a third surface 721, a fourth surface 722 opposite to the third surface 721, and a second lateral surface 723 surrounding at least a portion of the third surface 721 and the fourth surface 722. For example, the third surface 721 may be referred to as a front surface of the second housing 720, and the fourth surface 722 may be referred to as a rear surface of the second housing 720. The second lateral surface 723 may be connected to a periphery of the third surface 721 and a periphery of the fourth surface 722. The third surface 721, the fourth surface 722, and the second lateral surface 723 may form an internal space of the second housing 720. For example, at least one component may be disposed in a space surrounded by the third surface 721, the fourth surface 722, and the second lateral surface 723.

For example, the flexible display 730 may be configured to display visual information. For example, the flexible display 730 may include a display area including a plurality of pixels. For example, an active area may be referred to as an active area displaying visual information. For example, the flexible display 730 may form at least a portion of a front surface of the housing 701. For example, the flexible display 730 may at least partially form the first surface 711 and the third surface 721.

For example, the flexible display 730 may include a first display area 731 forming at least a portion of the first surface 711 of the first housing, a second display area 732 forming at least a portion of the third surface 721 of the second housing, and a third display area 733 disposed between the first display area 731 and the second display area 732. For example, the first display area 731, the second display area 732, and the third display area 733 may at least partially form a front surface of the housing 701. For example, the foldable electronic device 101 may further include a sub display 735 distinguished from the flexible display 730. The sub display 735 may be disposed on the fourth surface 722 of the second housing 720. The sub display 735 may be referred to as a cover display.

For example, the at least one camera 740 may be configured to obtain an image based on receiving light from an external object of the foldable electronic device 101. For example, the at least one camera 740 may include first cameras 741, a second camera 742, or a third camera 743. For example, the first cameras 741 may be disposed in the first housing 710. For example, the first housing 710 may include at least one opening 741a overlapping the first cameras 741 when the foldable electronic device 101 is viewed from above. The first cameras 741 may obtain an image based on receiving light from outside of the foldable electronic device 101 through the at least one opening 741a.

For example, the second camera 742 may be disposed in the second housing 720. The second housing 720 may include at least one opening 742a overlapping the second camera 742 when the foldable electronic device 101 is viewed from above. The second camera 742 may obtain an image based on receiving light from outside of the foldable electronic device 101 through the at least one opening 742a.

For example, the third camera 743 may be disposed in the first housing 710. For example, the first display area 731 of the flexible display 730 may include at least one opening overlapping the third camera 743 when the flexible display 730 is viewed from above. The third camera 743 may obtain an image based on receiving light from outside of the flexible display 730 through the at least one opening.

For example, the second camera 742 and the third camera 743 may be disposed under the flexible display 730 (e.g., in the −z direction). For example, the second camera 742 and/or the third camera 743 may include an under display camera (UDC) and/or a punch hole camera.

For example, the first housing 710 and the second housing 720 may be rotatably coupled. For example, the second housing 720 may be rotatably coupled to the first housing 710 through the hinge structure 750.

For example, the hinge structure 750 may rotatably connect the first housing 710 and the second housing 720. The hinge structure 750 may be disposed between the first housing 710 and the second housing 720 of the foldable electronic device 101 such that the foldable electronic device 101 may be folded. The hinge structure 750 may enable the foldable electronic device 101 to change from the folded state to the unfolded state. The hinge structure 750 may enable the foldable electronic device 101 to change from the folded state to the unfolded state. The hinge structure 750 may maintain the foldable electronic device 101 in an intermediate state between the unfolded state and the folded state.

For example, the unfolded state may be referred to as a state in which a first direction in which the first display area 730a faces and a second direction in which the second display area 730b faces are the same. For example, the folded state may be referred to as a state in which the first direction is opposite to the second direction. When the foldable electronic device 101 is in the folded state, the first housing 710 and the second housing 720 may overlap or may be superimposed.

For example, when the foldable electronic device 101 is in the folded state and the intermediate state, the first direction and the second direction may be different from each other. For example, when the foldable electronic device 101 is in the folded state, the first direction and the second direction may be opposite to each other. For example, when the foldable electronic device 101 is in the intermediate state, the first direction may have an inclination (e.g., an angle between 0 degrees and 180 degrees) with respect to the second direction.

For example, the foldable electronic device 101 may be rotatable based on a folding axis f. The folding axis f may be referred to as a virtual line extending along a direction (e.g., the y-axis) parallel to a length direction of the foldable electronic device 101 or a direction (e.g., the x-axis) parallel to a width direction of the foldable electronic device 101.

For example, the foldable electronic device 101 may include at least one conductive portion 714a and 724a and at least one non-conductive portion 714b and 724b included in the first lateral surface 713 and/or the third lateral surface 723. For example, the at least one conductive portion 714a and 724a may be separated from another conductive portion in the first lateral surface 713 and/or the third lateral surface 723 by contacting the at least one non-conductive portion 714b and 724b. The at least one conductive portion 714a and 724a may operate as an antenna radiator to be used for communication with an external electronic device.

Referring to FIG. 7C, the hinge structure 750 may include a hinge cover 751, a first hinge plate 752, a second hinge plate 753, and a hinge module 754. The hinge cover 751 may surround internal components of the hinge structure 750 and may form an outer surface of the hinge structure 750. For example, when the foldable electronic device 101 is in the folded state, at least a portion of the hinge cover 751 may be exposed to the outside of the foldable electronic device 101 through a space between the first housing 710 and the second housing 720. According to an embodiment, when the foldable electronic device 101 is in the unfolded state, the hinge cover 751 may not be exposed to the outside of the foldable electronic device 101 by being covered by the first housing 710 and the second housing 720.

For example, the first hinge plate 752 and the second hinge plate 753 may rotatably connect the first housing 710 and the second housing 720 by being operably coupled to the first housing 710 and the second housing 720, respectively. For example, the first hinge plate 752 may be operably coupled to a first frame 715 of the first housing 710, and the second hinge plate 753 may be operably coupled to a second frame 727 of the second housing 720. As the first hinge plate 752 and the second hinge plate 753 are operably coupled to the first frame 715 and the second frame 727, respectively, the first housing 710 and the second housing 720 may be rotatable according to rotation of the first hinge plate 752 and the second hinge plate 753.

The hinge module 754 may rotate the first hinge plate 752 and the second hinge plate 753. For example, the hinge module 754 may rotate the first hinge plate 752 and the second hinge plate 753 with respect to the folding axis f, by including rotatable gears engaged with each other.

For example, the first housing 710 may include a first frame 715 and a rear cover 716. The first frame 715 may be disposed inside the first housing 710 and may support at least one component disposed in the first housing 710. The rear cover 716 may at least partially form the second surface 722 of the first housing 710. For example, the second housing 720 may include a second frame 727. The second frame 727 may be disposed inside the second housing 720 and may support at least one component disposed in the second housing 720. For example, the sub display 735 may be disposed under the second frame 727 (e.g., in the −z direction).

The example foldable electronic device 101 may include a plurality of electronic components for implementing various functions in addition to the at least one camera 740 described above. For example, the foldable electronic device 101 may include a first printed circuit board 761, a second printed circuit board 762, a connection structure (e.g., a flexible printed circuit board) 763, and/or a battery 189. The above-described electronic components are merely examples, and are not limited thereto.

For example, the first printed circuit board 761 and the second printed circuit board 762 may respectively provide electrical connections of components in the foldable electronic device 101. For example, the first printed circuit board 761 may be disposed in the first housing 710, and the second printed circuit board 762 may be disposed in the second housing 720. The first printed circuit board 761 may provide an electrical connection between electronic components disposed in the first housing 710. The second printed circuit board 762 may provide an electrical connection between electronic components disposed in the second housing 720. The connection structure 763 may electrically connect the first printed circuit board 761 and the second printed circuit board 762. For example, the connection structure 763 may extend from the first printed circuit board 761 to the second printed circuit board 762 across the hinge structure 750. For example, the connection structure 763 may be at least partially overlapped with the hinge structure 750.

For example, the battery 189, which is a device for supplying power to at least one component of the foldable electronic device 101, may include, for example, a non-rechargeable primary battery and/or a rechargeable secondary battery.

For example, the foldable electronic device 101 may include a plurality of antennas ANT1, ANT2, ANT3, and ANT4 to be used for communication with an external electronic device. For example, the foldable electronic device 101 may include a main antenna ANT1, a sub antenna ANT2, an ultra-wide band (UWB) antenna ANT3, and/or an antenna ANT4 for short-range wireless communication. However, the disclosure is not limited thereto.

Hereinafter, one or more components to be described in greater detail below with reference to drawings may be implemented together with the components of the foldable electronic device 101 described with reference to FIGS. 7A, 7B, and 7C. The same reference numerals may be assigned to the same components as those described above, and redundant descriptions may be omitted.

In the present disclosure, a relative term such as “above” and “under” may be used to describe a relative position between components. For example, when the foldable electronic device 101 illustrated in the drawings is inverted, “above” and “under” may be interchanged.

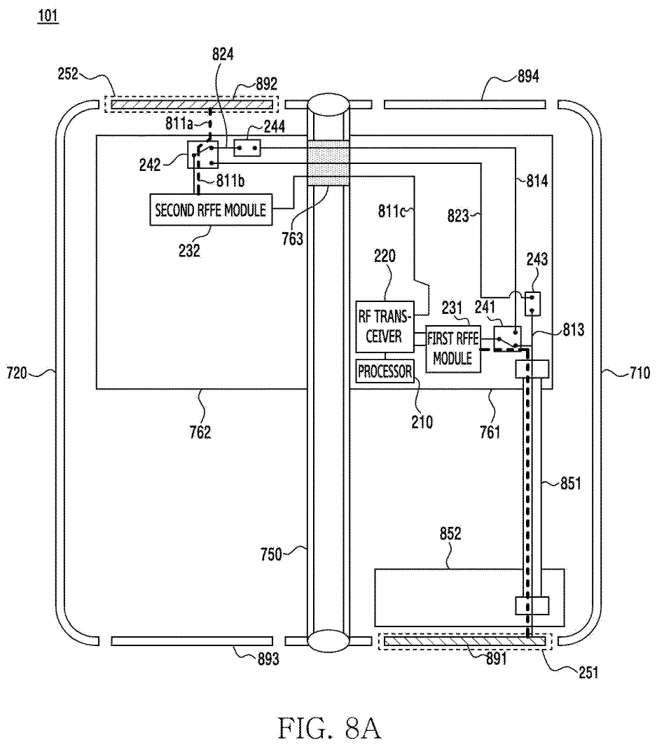

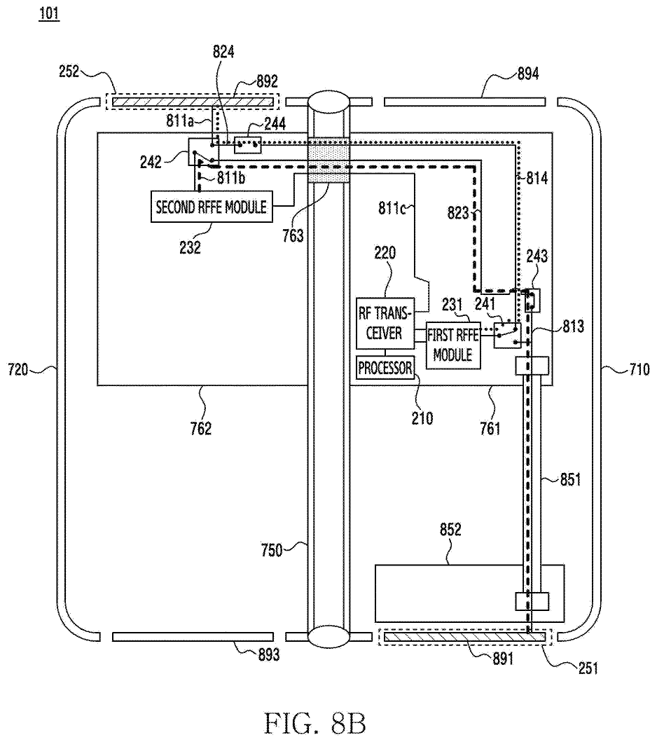

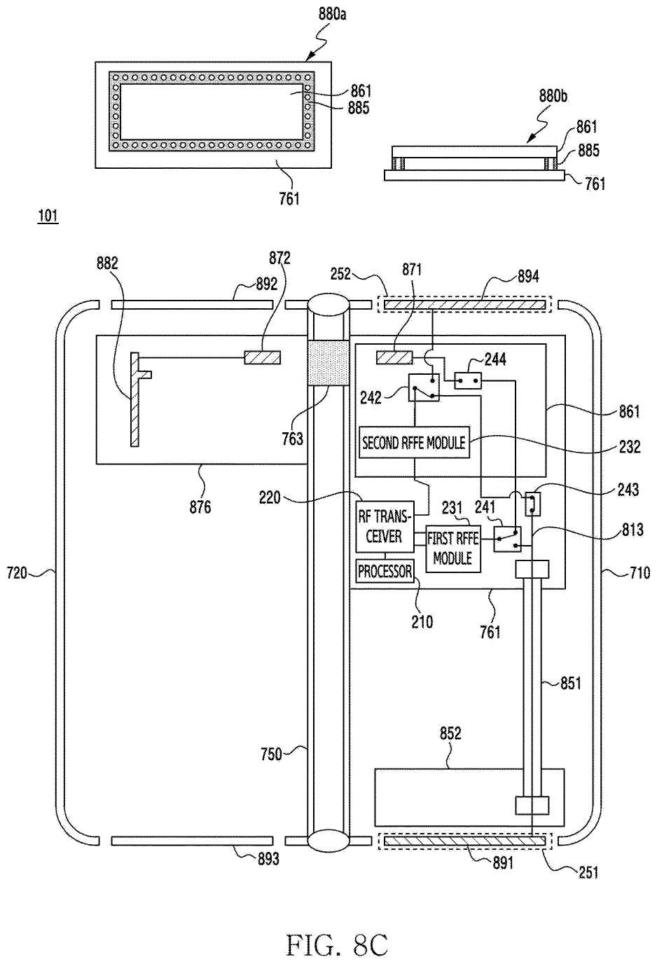

FIGS. 8A, 8B, and 8C are diagrams illustrating examples of components for antenna switching diversity in a foldable-type electronic device (e.g., the electronic device 101) according to various example embodiments. In order to describe the electronic device 101, the structure illustrated in FIGS. 7A to 7C may be used. However, other components of FIGS. 7A to 7C are not interpreted as limiting FIGS. 8A and 8B.

Referring to FIGS. 8A and 8B, the electronic device 101 may include a processor 210, an RF transceiver 220, a first RFFE module 231, a second RFFE module 232, a first antenna 251, and a second antenna 252. The electronic device 101 may include a plurality of switching circuits (e.g., a first switching circuit 241, a second switching circuit 242, a third switching circuit 243, and/or a fourth switching circuit 244) for antenna switching diversity. The same reference numerals may denote the same description. FIG. 8A illustrates a connection state of the plurality of switching circuits in a first connection mode. FIG. 8B illustrates a connection state of the plurality of switching circuits in a second connection mode.

The electronic device 101 may include a first housing 710 and a second housing 720. The second housing 720 may be configured to be rotatable with respect to the first housing 710. The first housing 710 may include at least one conductive portion. For example, the at least one conductive portion may be formed on a lateral surface of the first housing 710. For example, the at least one conductive portion may include a first conductive portion 891 and/or a fourth conductive portion 894. For example, the first conductive portion 891 may be formed through segments that are non-conductive portions of the first housing 710. The first conductive portion 891 may be used as a radiator of the first antenna 251 for transmission or reception of a signal. The second housing 720 may include at least one conductive portion. The at least one conductive portion may be formed on a lateral surface of the second housing 720. For example, the at least one conductive portion may include a second conductive portion 892 and/or a third conductive portion 893. For example, the second conductive portion 892 may be formed through segments that are non-conductive portions of the second housing 720. The second conductive portion 892 may be used as a radiator of the second antenna 252 for transmission or reception of a signal. A first printed circuit board 761 may be disposed in the first housing 710 of the electronic device 101. For example, the processor 210, the RF transceiver 220, the first RFFE module 231, the first switching circuit 241, and the third switching circuit 243 may be disposed on the first printed circuit board 761. A second printed circuit board 762 may be disposed in the second housing 720 of the electronic device 101. For example, the second RFFE module 232, the second switching circuit 242, and the fourth switching circuit 244 may be disposed on the second printed circuit board 762. For example, a third printed circuit board 852 disposed in the first housing 710 of the electronic device 101 may include elements (e.g., a tuning circuit, or a tuning element) for the first conductive portion 891 corresponding to the first antenna 251. The electronic device 101 may include a connection member 851 (e.g., flexible RF cable (FRC), or FPCB). The connection member 851 may be used for an electrical connection between the first printed circuit board 761 and the third printed circuit board 852. A transmission signal may be provided to the first antenna 251 through the connection member 851. The transmission signal may be transmitted to the first antenna 251 through the first RFFE module 231 and the first switching circuit 241 in the first connection mode or may be transmitted to the first antenna 251 through the second RFFE module 232, the second switching circuit 242, and the third switching circuit 243 in the second connection mode.

In an embodiment, in order to reduce a path loss, the first RFFE module 231 disposed on the first printed circuit board 761 may be disposed as close as possible to the first conductive portion 891. In order to reduce a path loss, the second RFFE module 232 disposed on the second printed circuit board 762 may be disposed close to the second conductive portion 892. The hinge structure 750 may be disposed between the first housing 710 and the second housing 720. An electrical connection between the first printed circuit board 761 and the second printed circuit board 762 may be formed through the hinge structure 750. As the first RFFE module 231 and the first switching circuit 241 are disposed on the first printed circuit board 761 and the second RFFE module 232 and the second switching circuit 242 are disposed on the second printed circuit board 762, a plurality of wirings may be formed through a connection structure 763 (e.g., FPCB) of the hinge structure 750. Hereinafter, a wiring for an electrical connection is described as being formed through the connection structure 763, but the present disclosure is not limited thereto. Although not illustrated in FIGS. 8A and 8B, an electrical connection between the first printed circuit board 761 and the second printed circuit board 762 may be formed through a stacked structure using an interposer, in addition to the hinge structure 750.

As the second RFFE module 232 disposed on the second printed circuit board 762 is connected to the second conductive portion 892 (e.g., a radiator of the second antenna 252) of the second housing 720, lengths of wirings between components on a path from the RF transceiver 220 to the second antenna 252 may vary. For example, as the second RFFE module 232 is located closer to the second antenna 252, a length of a wiring 811c between the RF transceiver 220 and the second RFFE module 232 may increase. As the second RFFE module 232 is located closer to the second antenna 252, a length of a wiring 811a between the second antenna 252 and the second switching circuit 242 and a length of a wiring 811b between the second switching circuit 242 and the second RFFE module 232 may decrease. A distance between the RF transceiver 220 and the second RFFE module 232 may be longer than a distance between the second antenna 252 and the second RFFE module 232.

A wiring 813 between the first switching circuit 241 and the third switching circuit 243 may be formed. A wiring 824 between the second switching circuit 242 and the fourth switching circuit 244 may be formed. A wiring 814 between the first switching circuit 241 and the fourth switching circuit 244 may be formed. A wiring 823 between the second switching circuit 242 and the third switching circuit 243 may be formed. According to an embodiment, the wiring 814, the wiring 823, and/or the wiring 811c may be formed through the connection structure 763 (e.g., FPCB).

In the first connection mode, the first switching circuit 241 may be configured to electrically connect the first RFFE module 231 to the first antenna 251. In the first connection mode, the second switching circuit 242 may be configured to electrically connect the second RFFE module 232 to the second antenna 252. In the first connection mode, the third switching circuit 243 may be opened. Although not illustrated in FIG. 8A, the third switching circuit 243 may connect the first switching circuit 241 and a first stub circuit 461 for impedance matching to the first antenna 251 in the first connection mode, instead of being opened. In the first connection mode, the fourth switching circuit 244 may be opened. Although not illustrated in FIG. 8A, the fourth switching circuit 244 may connect the second switching circuit 242 and the second stub circuit 462 for impedance matching to the second antenna 252 in the first connection mode, instead of being opened.

In the second connection mode, the first switching circuit 241 may be configured to electrically connect the first RFFE module 231 to the second antenna 252. In the second connection mode, the second switching circuit 242 may be configured to electrically connect the second RFFE module 232 to the first antenna 251. In the second connection mode, the third switching circuit 243 may be configured to electrically connect the second switching circuit 242 and the first antenna 251. In the second connection mode, the fourth switching circuit 244 may be configured to electrically connect the first switching circuit 241 and the second antenna 252.

Referring to FIG. 8C, the electronic device 101 may include a processor 210, an RF transceiver 220, a first RFFE module 231, a second RFFE module 232, a first antenna 251, and a second antenna 252. The electronic device 101 may include a plurality of switching circuits (e.g., a first switching circuit 241, a second switching circuit 242, a third switching circuit 243, and/or a fourth switching circuit 244) for antenna switching diversity. The same reference numerals may denote the same description.

The electronic device 101 may include a first housing 710 and a second housing 720. The first housing 710 may include at least one conductive portion. For example, the at least one conductive portion may include a first conductive portion 891 and/or a fourth conductive portion 894. The second housing 720 may include at least one conductive portion. For example, the at least one conductive portion may include a second conductive portion 892 and/or a third conductive portion 893. A first printed circuit board 761 may be disposed in the first housing 710 of the electronic device 101. For example, the processor 210, the RF transceiver 220, the first RFFE module 231, the first switching circuit 241, and the third switching circuit 243 may be disposed on the first printed circuit board 761. A second printed circuit board 861 may be disposed in the first housing 710 of the electronic device 101. For example, the second RFFE module 232, the second switching circuit 242, and the fourth switching circuit 244 may be disposed on the second printed circuit board 861.

The second printed circuit board 861 on which the second RFFE module 232 is disposed may be electrically connected to the first printed circuit board 761 on which the first RFFE module 231 is disposed, through an interposer 885. The interposer 885 may indicate a layer including wirings for electrical connection. For example, the first printed circuit board 761, the interposer 885, and the second printed circuit board 861 may be stacked in an order of the first printed circuit board 761, the interposer 885, and the second printed circuit board 861. An example 880a represents a view of the first printed circuit board 761 and the second printed circuit board 861 viewed in a first direction (e.g., a direction toward a display of the electronic device 101). An example 880b represents a view of the first printed circuit board 761 and the second printed circuit board 861 viewed in a second direction (e.g., a direction in which an upper surface or a lower surface of the electronic device 101 face). For example, the RF transceiver 220 and the second RFFE module 232 may be electrically connected through at least a portion of the interposer 885. For example, an electrical connection between the first switching circuit 241 and the fourth switching circuit 244 may be formed through at least a portion of the interposer 885. For example, an electrical connection between the second switching circuit 242 and the third switching circuit 243 may be formed through at least a portion of the interposer 885.

The electronic device 101 may include a third printed circuit board 852 disposed in the first housing 710. For example, the third printed circuit board 852 disposed in the first housing 710 of the electronic device 101 may include elements (e.g., a tuning circuit, or a tuning element) for the first conductive portion 891 corresponding to the first antenna 251. In the first connection mode, the first RFFE module 231 may be electrically connected to the first conductive portion 891 through the first switching circuit 241. In the first connection mode, the second RFFE module 232 may be connected to the fourth conductive portion 894 through the second switching circuit 242. In the second connection mode, the first RFFE module 231 may be electrically connected to the fourth conductive portion 894 through the first switching circuit 241. In the second connection mode, the second RFFE module 232 may be electrically connected to the first conductive portion 891 through the second switching circuit 242. The first conductive portion 891 may correspond to a radiator of the first antenna 251. The fourth conductive portion 894 may correspond to a radiator of the second antenna 252.

A distance between a portion (e.g., the fourth conductive portion 894) of the first housing 710 and a portion (e.g., the second conductive portion 892) of the second housing 720 may vary according to a state (e.g., the unfolded state, or the folded state) of the electronic device 101. For example, the hinge structure 750 may enable the electronic device 101 to change from the folded state to the unfolded state. For example, the hinge structure 750 may enable the electronic device 101 to change from the unfolded state to the folded state. In order to increase radiation performance in the folded state, the electronic device 101 may include a third antenna 882, a first conductive member 871, and a second conductive member 872. For example, the first conductive member 871 may be disposed on the second printed circuit board 861. The first conductive member 871 may be electrically connected to the fourth conductive portion 894. The electronic device 101 may include a fourth printed circuit board 876 disposed in the second housing 720. The fourth printed circuit board 876 disposed in the second housing 720 of the electronic device 101 may include the third antenna 882 and the second conductive member 872. The third antenna 882 may include a conductive portion (e.g., a patch, a conductive pattern, a portion of a metal frame, or a conductive surface of a slot antenna) that may be used as a radiator.

In the second connection mode, a signal from the first RFFE module 231 may be provided to the fourth conductive portion 894 through the first switching circuit 241 and the fourth switching circuit 244. The fourth conductive portion 894 may be used to radiate the signal. The signal may be provided to the first conductive member 871. For example, in the unfolded state, a distance between the first conductive member 871 and the second conductive member 872 may not be sufficient to feed a signal through coupling. Through the hinge structure 750, a state of the electronic device 101 may be changed from the unfolded state to the folded state. In the folded state, a distance between the first conductive member 871 and the second conductive member 872 may be shorter than a distance between the first conductive member 871 and the second conductive member 872 in the unfolded state. In the folded state, as the first conductive member 871 and the second conductive member 872 become close to each other, the first conductive member 871 and the second conductive member 872 may be coupled. For example, in the folded state, when the electronic device 101 is viewed from a direction (e.g., a direction toward a display area), at least a portion of the second conductive member 872 may overlap the first conductive member 871. Through coupling between the first conductive member 871 and the second conductive member 872, the signal may be provided to the third antenna 882. In the folded state, the electronic device 101 may radiate the signal through the second antenna 252 and the third antenna 882. In the folded state and the second connection mode of the electronic device 101, since not only the second antenna 252 but also the third antenna 882 is used for radiation, radiation performance of the electronic device 101 may be improved.

In FIG. 8C, the third antenna 882 fed through PCBs (e.g., the first printed circuit board 761 and the second printed circuit board 861) stacked through the interposer 855 and conductive members (e.g., the first conductive member 871 and the second conductive member 872) is illustrated, but the present disclosure is not limited thereto. For example, in the structure illustrated in FIG. 8C, the third antenna 882, the first conductive member 871, and the second conductive member 872 may be omitted.

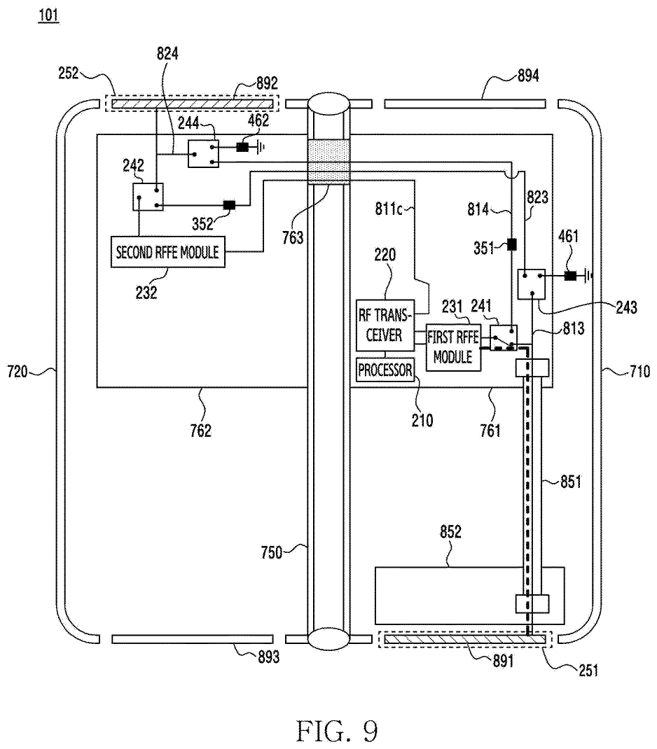

FIG. 9 is a diagram illustrating examples of components for antenna switching diversity in a foldable-type electronic device (e.g., the electronic device 101) according to various example embodiments. A matching circuit (e.g., the first matching circuit 351 or the second matching circuit 352) or a stub circuit (e.g., the first stub circuit 461 or the second stub circuit 462) described with reference to FIG. 3, FIG. 4A, and FIG. 4B may be included in the foldable-type electronic device described with reference to FIGS. 8A to 8B.

Referring to FIG. 9, the electronic device 101 may include a processor 210, an RF transceiver 220, a first RFFE module 231, a second RFFE module 232, a first antenna 251, and a second antenna 252. The electronic device 101 may include a plurality of switching circuits (e.g., a first switching circuit 241, a second switching circuit 242, a third switching circuit 243, and/or a fourth switching circuit 244) for antenna switching diversity. The same reference numerals may denote the same description.

According to an embodiment, the electronic device 101 may include a first matching circuit 351 and/or a second matching circuit 352. The first matching circuit 351 may be connected to the first switching circuit 241. In the first connection mode, the first switching circuit 241 may be configured to electrically connect the first RFFE module 231 to the first antenna 251. The second matching circuit 352 may be connected to the second switching circuit 242. In the first connection mode, the second switching circuit 242 may be configured to electrically connect the second RFFE module 232 to the second antenna 252. According to an embodiment, the first matching circuit 351 may be disposed on the first printed circuit board 761. The second matching circuit 352 may be disposed on the second printed circuit board 762.

According to an embodiment, the electronic device 101 may include a first stub circuit 461 and/or a second stub circuit 462. The first stub circuit 461 may be connected to the third switching circuit 243. For example, the third switching circuit 243 may include an SPDT switch. According to an embodiment, the first stub circuit 461 may be disposed on the first printed circuit board 761. The first stub circuit 461 may be used for impedance matching of a transmission signal transmitted through the first RFFE module 231 and the first antenna 251. Through the first stub circuit 461, impedance matching for signal transmission of the first antenna 251 may be performed. The second stub circuit 462 may be connected to the fourth switching circuit 244. For example, the fourth switching circuit 244 may include an SPDT switch. According to an embodiment, the second stub circuit 462 may be disposed on the second printed circuit board 762. The second stub circuit 462 may be used for impedance matching of a reception signal received through the second RFFE module 232 and the second antenna 252. Through the second stub circuit 462, impedance matching for signal reception of the second antenna 252 may be performed.

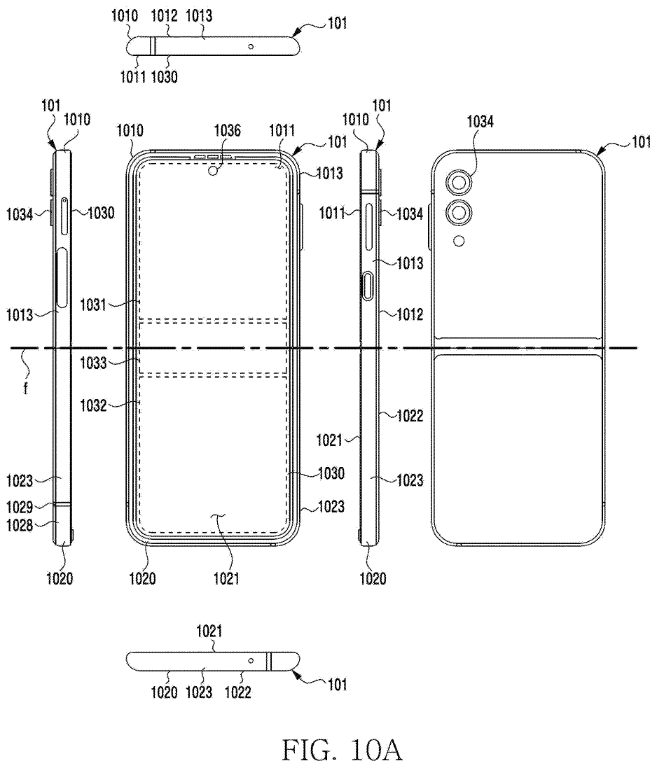

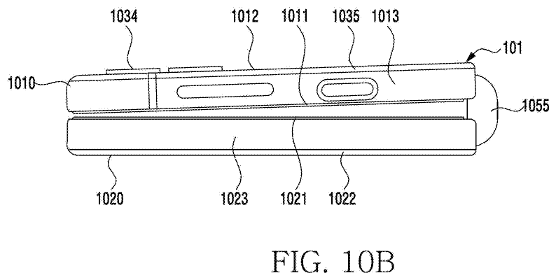

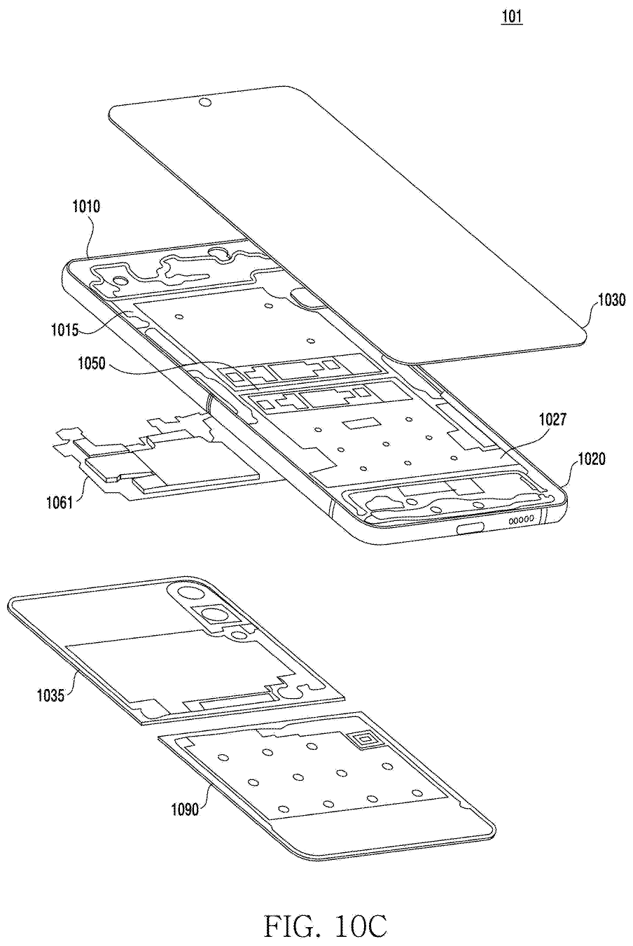

FIGS. 10A, 10B, and 10C are diagrams illustrating examples of another foldable-type electronic device (e.g., the electronic device 101) according to various example embodiments. FIG. 10A illustrates an unfolded state of the electronic device 101 according to various example embodiments. FIG. 10B illustrates a folded state of the electronic device 101 according to various example embodiments. FIG. 10C is an exploded perspective view of the electronic device 101 according to various example embodiments.

Referring to FIGS. 10A, 10B, and 10C, the electronic device 101 may include a first housing 1010, a second housing 1020, and a display 1030.

The first housing 1010 may include a first surface 1011, a second surface 1012 faced away from the first surface 1011, and a first lateral surface 1013 surrounding at least a portion of the first surface 1011 and the second surface 1012. The second housing 1020 may further include at least one camera 1034 and a display panel 1035 visible through a portion of the second surface 1012. The first housing 1010 may provide a space formed by the first surface 1011, the second surface 1012, and the first lateral surface 1013 as a space for disposing components of the electronic device 101. The first lateral surface 1013 and a second lateral surface 1023 may include a conductive material, a non-conductive material, or a combination thereof. For example, the first lateral surface 1013 and the second lateral surface 1023 may include a conductive portion 1028 and a non-conductive portion 1029. The conductive portion 1028 may include a plurality of conductive members, and the plurality of conductive members may be spaced apart from each other. The non-conductive portion 1029 may be disposed between the plurality of conductive members. An antenna structure may be formed by at least a portion of the plurality of conductive members and the plurality of non-conductive members or a combination thereof.

The second housing 1020 may include a third surface 1021, a fourth surface 1022 faced away from the third surface 1021, and a second lateral surface 1023 surrounding at least a portion of the third surface 1021 and the fourth surface 1022. The fourth surface 1022 may further include a rear plate 1090 disposed on the fourth surface 1022.

The second lateral surface 1023 may be pivotably (or rotatably) connected to the first lateral surface 1013 through a hinge structure 1050 disposed in a hinge cover 1055. The hinge structure 1050 may include a hinge plate. For example, the hinge plate may include a first hinge plate and a second hinge plate. The first hinge plate may be connected to the first housing 1010, and the second hinge plate may be connected to the second housing 1020. The second housing 1020 may provide a space formed by the third surface 1021, the fourth surface 1022 faced away from the third surface 1021, and the lateral surface 1023 surrounding at least a portion of the third surface 1021 and the fourth surface 1022, as a space for disposing components of the electronic device 101. The display 1030 may include a window exposed to the outside. The window may protect a surface of the display 1030 and may be formed of a transparent member to transmit visual information provided from the display 1030 to the outside. The window may include a glass material such as ultra-thin glass (UTG) or a polymer material such as polyimide (PI). The display 1030 may include a first display area 1031 disposed on the first surface 1011 of the first housing, a second display area 1032 disposed on the third surface 1021 of the second housing, and a third display area 1033 between the first display area 1031 and the second display area 1032. At least a portion of the third display area 1033 may be disposed on the hinge structure 1050.

For example, an opening may be formed in a portion of a screen display area of the display 1030, or a recess or an opening may be formed in a support member (e.g., a bracket) supporting the display 1030. The electronic device 101 may include at least one camera aligned with the recess or the opening. For example, the first display area 1031 may further include at least one camera 1036 capable of obtaining an image from the outside through a portion of the first display area 1031. For example, the at least one camera 1036 may be included on a rear surface of the display 1030 corresponding to the first display area 1031 or the second display area 1032 of the display 1030. For example, the at least one camera 1036 may be disposed under the display 1030 and may be surrounded by the display 1030. The at least one camera 1036 may be surrounded by the display 1030 and may not be exposed to the outside. However, the disclosure is not limited thereto, and the display 1030 may include an opening exposing the at least one camera 1036 to the outside. Although not illustrated in FIGS. 10A and 10B, the display 1030 may further include a rear surface opposite to the front surface. The display 1030 may be supported by a first support member 1015 of the first housing 1010 and a second support member 1027 of the second housing 1020.

The hinge structure 1050 may be configured to rotatably connect the first support member 1015 fastened to the first hinge plate and the second support member 1027 fastened to the second hinge plate. The hinge cover 1055 surrounding the hinge structure 1050 may be at least partially exposed through a space between the first housing 1010 and the second housing 1020 while the electronic device 101 is in the folded state. The hinge cover 1055 may be covered by the first housing 1010 and the second housing 1020 while the electronic device 101 is in the unfolded state.

The electronic device 101 may be folded based on a folding axis f passing through the hinge cover 1055. For example, the hinge cover 1055 may be disposed between the first housing 1010 and the second housing 1020 of the electronic device 101 to enable the electronic device 101 to be bent, curved, or folded. For example, the first housing 1010 may be connected to the second housing 1020 through the hinge structure 1050 disposed in the hinge cover 1055 and may rotate based on the folding axis f.

The electronic device 101 may be folded such that the first housing 1010 and the second housing 1020 face each other by rotating based on the folding axis f. The electronic device 101 may be folded such that the first housing 1010 and the second housing 1020 overlap or may be superimposed.

Referring to FIG. 10C, the electronic device 101 may include a first housing 1010, a second housing 1020, a hinge structure 1050, a display 1030, a printed circuit board 1061, a display panel 1035, and a rear plate 1090. For example, the electronic device 101 may omit at least one of the components or may additionally include another component.

For example, the hinge structure 1050 may include a hinge plate. For example, the hinge structure 1050 may include a hinge gear by which the first housing 1010 and the second housing 1020 are pivotable.

For example, the first support member 1015 may be partially surrounded by the first lateral surface 1013. For example, the first support member 1015 may be integrally formed with the first lateral surface 1013. For example, the second support member 1027 may be partially surrounded by the second lateral surface 1023. For example, the second support member 1027 may be integrally formed with the second lateral surface 1023. However, the disclosure is not limited thereto. For example, the first support member 1015 may be formed separately from the first lateral surface 1013. For example, the second support member 1027 may be formed separately from the second lateral surface 1023.

For example, a surface of the first support member 1015 may be coupled to the display 1030, and another surface of the first support member 1015 may be coupled to the display panel 1035. A surface of the second support member 1027 may be coupled to the display 1030, and another surface of the second support member 1027 may be coupled to the rear plate 1090.

For example, a printed circuit board 1061 and a battery may be disposed between a surface formed by the first support member 1015 and the second support member 1027 and a surface formed by the display panel 1035 and the rear plate 1090. The printed circuit board 1061 may be electrically connected to components for implementing various functions of the electronic device 101.

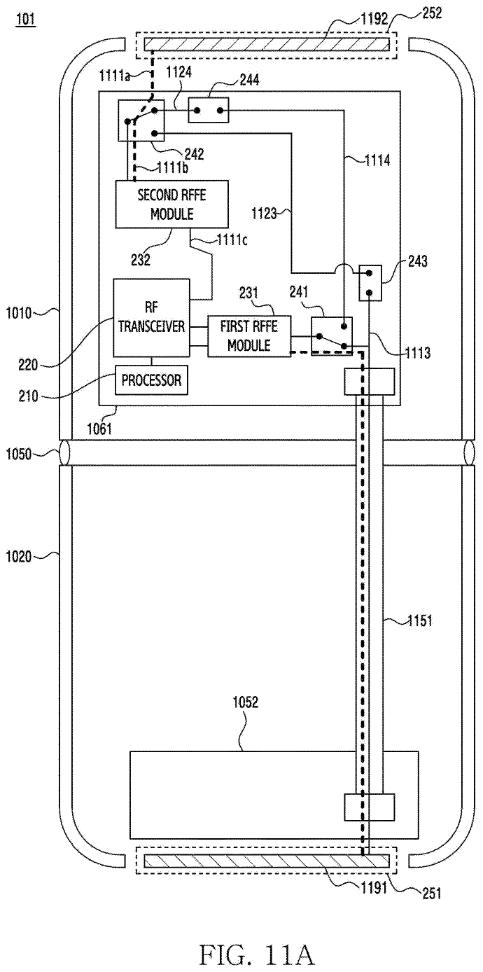

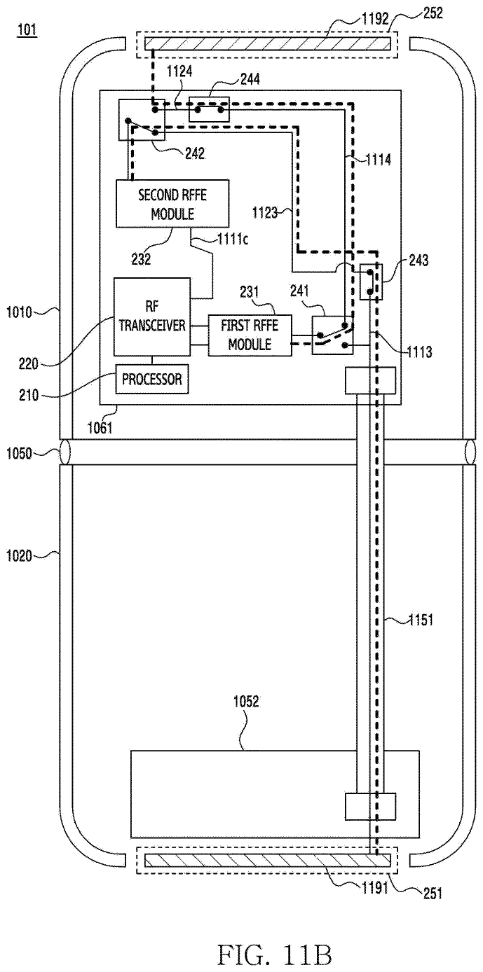

FIGS. 11A and 11B are diagrams illustrating examples of components for antenna switching diversity in another foldable-type electronic device (e.g., the electronic device 101) according to various example embodiments. In order to describe the electronic device 101, the structure illustrated in FIGS. 10A to 10C may be used. However, other components of FIGS. 10A to 10C are not interpreted as limiting FIGS. 11A and 11B.

Referring to FIGS. 11A and 11B, the electronic device 101 may include a processor 210, an RF transceiver 220, a first RFFE module 231, and a second RFFE module 232. The electronic device 101 may include a plurality of switching circuits (e.g., a first switching circuit 241, a second switching circuit 242, a third switching circuit 243, and/or a fourth switching circuit 244) for antenna switching diversity. The same reference numerals may denote the same description. FIG. 11A illustrates a connection state of the plurality of switching circuits in a first connection mode. FIG. 11B illustrates a connection state of the plurality of switching circuits in a second connection mode.

The electronic device 101 may include a first housing 1010 and a second housing 1020. The second housing 1020 may be configured rotatably with respect to the first housing 1010. The first housing 1010 and the second housing 1020 may be connected through a hinge structure 1050. For example, antennas for the antenna switching diversity may include a first antenna 251 included in the second housing 1020 and a second antenna 252 included in the first housing 1010. For example, the first housing 1010 may include at least one conductive portion. The at least one conductive portion may be formed on a lateral surface of the first housing 1010. For example, the at least one conductive portion may include a second conductive portion 1192. For example, the second conductive portion 1192 may be formed through segments that are non-conductive portions of the first housing 1010. The second conductive portion 1192 may be used as a radiator of the second antenna 252 for transmission or reception of a signal. The second housing 1020 may include at least one conductive portion. The at least one conductive portion may be formed on a lateral surface of the second housing 1020. For example, the at least one conductive portion may include a first conductive portion 1191. For example, the first conductive portion 1191 may be formed through segments that are non-conductive portions of the second housing 1020. The first conductive portion 1191 may be used as a radiator of the first antenna 251 for transmission or reception of a signal.

According to an embodiment, the processor 210, the RF transceiver 220, the first RFFE module 231, the second RFFE module 232, the first switching circuit 241, the second switching circuit 242, the third switching circuit 243, and/or the fourth switching circuit 244 may be disposed on the printed circuit board 1061. The electronic device 101 may include a printed circuit board 1052. For example, the printed circuit board 1052 may include elements (e.g., a tuning circuit, or a tuning element) for a first conductive portion corresponding to the first antenna 251. The electronic device 101 may include a connection member 1151 (e.g., flexible RF cable (FRC), or FPCB). The connection member 1151 may be used for an electrical connection between the printed circuit board 1061 and the printed circuit board 1052. A transmission signal may be provided to the first antenna 251 through the connection member 1151. The transmission signal may be transmitted to the first antenna 251 through the first RFFE module 231 and the first switching circuit 241 in the first connection mode or may be transmitted to the first antenna 251 through the second RFFE module 232, the second switching circuit 242, and the third switching circuit 243 in the second connection mode.

According to an embodiment, in order to reduce a path loss, the first RFFE module 231 may be disposed as close as possible to the first conductive portion 1191. In order to reduce a path loss, the second RFFE module 232 may be disposed as close as possible to the second conductive portion 1192. Due to a physical separation between the first housing 1010 and the second housing 1020, the first conductive portion 1191 (e.g., the first antenna 251) and the second conductive portion 1192 (e.g., the second antenna 252) may be physically spaced apart from each other. As each RFFE module is disposed close to a corresponding antenna, the first switching circuit 241 connected to the first RFFE module 231 and the second switching circuit 242 connected to the second RFFE module 232 may be spaced apart from each other to implement an antenna switching diversity technology. As the second RFFE module 232 is located close to the second conductive portion 1192 corresponding to the second antenna 252, lengths of wirings between components on a path from the RF transceiver 220 to the second antenna 252 may vary. For example, as the second RFFE module 232 is located closer to the second antenna 252, a length of a wiring 1111c between the RF transceiver 220 and the second RFFE module 232 may increase. As the second RFFE module 232 is located closer to the second antenna 252, a length of a wiring 1111a between the second antenna 252 and the second switching circuit 242 and a length of a wiring 1111b between the second switching circuit 242 and the second RFFE module 232 may decrease. For example, a distance between the RF transceiver 220 and the second RFFE module 232 may be longer than a distance between the second antenna 252 and the second RFFE module 232.

According to an embodiment, a wiring 1113 between the first switching circuit 241 and the third switching circuit 243 may be formed. A wiring 1124 between the second switching circuit 242 and the fourth switching circuit 244 may be formed. A wiring 1114 between the first switching circuit 241 and the fourth switching circuit 244 may be formed. A wiring 1123 between the second switching circuit 242 and the third switching circuit 243 may be formed.

In the first connection mode, the first switching circuit 241 may be configured to electrically connect the first RFFE module 231 to the first antenna 251. In the first connection mode, the second switching circuit 242 may be configured to electrically connect the second RFFE module 232 to the second antenna 252. In the first connection mode, the third switching circuit 243 may be opened. Although not illustrated in FIG. 11A, the third switching circuit 243 may connect the first switching circuit 241 and the first stub circuit 461 for impedance matching to the first antenna 251 in the first connection mode, instead of being opened. In the first connection mode, the fourth switching circuit 244 may be opened. Although not illustrated in FIG. 11A, the fourth switching circuit 244 may connect the second switching circuit 242 and the second stub circuit 462 for impedance matching to the second antenna 252 in the first connection mode, instead of being opened.

In the second connection mode, the first switching circuit 241 may be configured to electrically connect the first RFFE module 231 to the second antenna 252. In the second connection mode, the second switching circuit 242 may be configured to electrically connect the second RFFE module 232 to the first antenna 251. In the second connection mode, the third switching circuit 243 may be configured to electrically connect the second switching circuit 242 and the first antenna 251. In the second connection mode, the fourth switching circuit 244 may be configured to electrically connect the first switching circuit 241 and the second antenna 252.

According to an example embodiment, the electronic device 101 is provided. The electronic device 101 may include a plurality of antennas including a first antenna 251 and a second antenna 252, a radio frequency (RF) transceiver 220, a first radio frequency front end (RFFE) module 231 electrically connected to the RF transceiver 220 and configured to transmit or receive a signal, a second RFFE module 232 electrically connected to the RF transceiver 220 and configured to receive a signal, and a plurality of switching circuits including a first switching circuit 241 connected to the first RFFE module 231 and a second switching circuit 242 connected to the second RFFE module 232. The first switching circuit 241 may be configured to selectively connect the first RFFE module 231 to the first antenna 251 in a first connection mode or to the second antenna 252 in a second connection mode. The second switching circuit 242 may be configured to selectively connect the second RFFE module 232 to the second antenna 252 in the first connection mode or to the first antenna 251 in the second connection mode.

According to an example embodiment, the plurality of switching circuits may include a third switching circuit 243 connected to a first path between the first switching circuit 241 and the first antenna 251, and a fourth switching circuit 244 connected to a second path between the second switching circuit 242 and the second antenna 252. The third switching circuit 243 may be configured to electrically disconnect the second switching circuit 242 and the first antenna 251 in the first connection mode, and to electrically connect the second switching circuit 242 and the first antenna 251 in the second connection mode. The fourth switching circuit 244 may be configured to electrically disconnect the first switching circuit 241 and the second antenna 252 in the first connection mode, and to electrically connect the first switching circuit 241 and the second antenna 252 in the second connection mode.

According to an example embodiment, the first switching circuit 241 may include a single pole double throw (SPDT) switch configured to selectively connect the first RFFE module 231 to the first antenna 251 or the second antenna 252. The second switching circuit 242 may include an SPDT switch configured to selectively connect the second RFFE module 232 to the first antenna 251 or the second antenna 252.

According to an example embodiment, the electronic device may further include a first matching circuit for the second antenna 252, connecting the first switching circuit 241 and the fourth switching circuit 244. The first switching circuit 241 may include a first end connected to the first antenna 251 and a second end connected to the second antenna 252. The second end of the first switching circuit 241 may be connected to the second antenna 252 through the first matching circuit and the fourth switching circuit 244.

According to an example embodiment, the electronic device may further include a second matching circuit for the first antenna 251, connecting the second switching circuit 242 and the third switching circuit 243. The second switching circuit 242 may include a first end connected to the second antenna 252 and a second end connected to the first antenna 251. The second end of the second switching circuit 242 may be connected to the first antenna 251 through the second matching circuit and the third switching circuit 243.

According to an example embodiment, the third switching circuit 243 may include a single pole single throw (SPST) switch configured to selectively connect the second switching circuit 242 to the first antenna 251 or the second antenna 252. The fourth switching circuit 244 may include an SPST switch configured to selectively connect the first switching circuit 241 to the first antenna 251 or the second antenna 252.

According to an example embodiment, the electronic device 101 may include a first stub circuit connected to the third switching circuit 243, and a second stub circuit connected to the fourth switching circuit 244. The third switching circuit 243 may include a first end connected to the second matching circuit of the second switching circuit 242 and a second end connected to the first stub circuit. The fourth switching circuit 244 may include a first end connected to the first matching circuit of the first switching circuit 241 and a second end connected to the second stub circuit.

According to an example embodiment, the third switching circuit 243 may include a single pole double throw (SPDT) switch configured to connect the first stub circuit to the first antenna 251 or connect the second RFFE module 232 to the first antenna 251. The fourth switching circuit 244 may include an SPDT switch configured to connect the second stub circuit to the second antenna 252 or connect the first RFFE module 231 to the second antenna 252.

According to an example embodiment, the first RFFE module 231 may include a transmission/reception module for transmission signal processing and reception signal processing. The second RFFE module 232 may include a reception module for reception signal processing. In the first connection mode, the first antenna 251 may be used for transmission of a signal. In the second connection mode, the second antenna 252 may be used for transmission of a signal.

According to an example embodiment, a distance between the first RFFE module 231 and the first antenna 251 may be shorter than a distance between the first RFFE module 231 and the second antenna 252. A distance between the second RFFE module 232 and the second antenna 252 may be shorter than a distance between the second RFFE module 232 and the first antenna 251.

According to an example embodiment, a distance between the second RFFE module 232 and the second antenna 252 may be shorter than a distance between the RF transceiver 220 and the second RFFE module 232.

According to an example embodiment, the electronic device 101 may further include a housing including a plurality of non-conductive portions and a plurality of conductive portions. The plurality of non-conductive portions may include a first non-conductive portion, a second non-conductive portion, a third non-conductive portion, and a fourth non-conductive portion. The plurality of conductive portions may include a first conductive portion disposed between the first non-conductive portion and the second non-conductive portion and a second conductive portion disposed between the third non-conductive portion and the fourth non-conductive portion. The first conductive portion may be used as a radiator of the first antenna 251. The second conductive portion may be used as a radiator of the second antenna 252. The first conductive portion may be disposed on a first lateral surface of the housing. The second conductive portion may be disposed on a second lateral surface opposite to the first lateral surface of the housing.

According to an example embodiment, an electronic device 101 is provided. The electronic device 101 may include a housing. The housing may include a first conductive portion and a second conductive portion formed on an outer lateral surface of the housing. The electronic device 101 may include a radio frequency (RF) transceiver 220, a first radio frequency front end (RFFE) module 231 electrically connected to the RF transceiver 220 and configured to transmit or receive a signal, a second RFFE module 232 electrically connected to the RF transceiver 220 and configured to receive a signal, a first switching circuit 241 connected to the first RFFE module 231, and a second switching circuit 242 connected to the second RFFE module 232. The first switching circuit 241 may be configured to selectively connect the first RFFE module 231 to the first conductive portion or the second conductive portion. The second switching circuit 242 may be configured to selectively connect the second RFFE module 232 to the first conductive portion or the second conductive portion.

According to an example embodiment, the electronic device 101 may include a first printed circuit board (PCB) 761 on which the RF transceiver 220, the first RFFE module 231, and the first switching circuit 241 are disposed, a second PCB 861 on which the second RFFE module 232 and the second switching circuit 242 are disposed, and an interposer 885 coupled between the first PCB 761 and the second PCB 861.

According to an example embodiment, the electronic device 101 may further include a first conductive member 871 electrically connected to the second conductive portion 894 and disposed on the second PCB 861, another housing 720 rotatably coupled to the housing 710, a substrate 762 included in the another housing 720, a third conductive portion 882 disposed on the substrate 762, and a second conductive member 872 electrically connected to the third conductive portion 882 and disposed on the substrate 762. The third conductive portion 882 may be used to radiate a transmission signal of the first RFFE module 231 through coupling between the first conductive member 871 and the second conductive member 872.

According to an example embodiment, the electronic device 101 may further include a third switching circuit 243 connected to a first path between the first switching circuit 241 and the first conductive portion and a fourth switching circuit 244 connected to a second path between the second switching circuit 242 and the second conductive portion. The third switching circuit 243 may be configured to electrically disconnect the second switching circuit 242 and the first conductive portion while the first RFFE module 231 is connected to the first conductive portion and the second RFFE module 232 is connected to the second conductive portion. The fourth switching circuit 244 may be configured to electrically disconnect the second switching circuit 242 and the second conductive portion while the first RFFE module 231 is connected to the second conductive portion and the second RFFE module 232 is connected to the first conductive portion.

According to an example embodiment, the first RFFE module 231 may include a transmission/reception module for transmission signal processing and reception signal processing. The second RFFE module 232 may include a reception module for reception signal processing. While the first RFFE module 231 is connected to the first conductive portion and the second RFFE module 232 is connected to the second conductive portion, the first conductive portion may be used for transmission of a signal. While the first RFFE module 231 is connected to the second conductive portion and the second RFFE module 232 is connected to the first conductive portion, the second conductive portion may be used for transmission of a signal. A distance between the second RFFE module 232 and the second conductive portion may be shorter than a distance between the RF transceiver 220 and the second RFFE module 232.

According to an example embodiment, the electronic device 101 may include a first printed circuit board (PCB) on which the RF transceiver 220, the first RFFE module 231, and the second RFFE module 232 are disposed, a second PCB, a connection member for connecting the first PCB and the second PCB. A tuning circuit for the first conductive portion may be further included. The first conductive portion may be disposed on a first lateral surface of the housing. The second conductive portion may be disposed on a second lateral surface opposite to the first lateral surface of the housing.

According to an example embodiment, an electronic device 101 is provided. The electronic device 101 may include a first housing, a second housing rotatably coupled to the first housing, a first antenna 251 included in the first housing, a second antenna 252 included in the second housing, a first printed circuit board (PCB) included in the first housing, a second PCB included in the second housing, a radio frequency (RF) transceiver 220 disposed on the first PCB, a first radio frequency front end (RFFE) module 231, disposed on the first PCB, electrically connected to the RF transceiver 220, and configured to transmit or receive a signal, a second RFFE module 232 disposed on the second PCB, electrically connected to the RF transceiver 220, and configured to receive a signal, a first switching circuit 241 disposed on the first PCB and connected to the first RFFE module 231, and a second switching circuit 242 disposed on the second PCB and connected to the second RFFE module 232. The first switching circuit 241 may be configured to selectively connect the first RFFE module 231 to the first antenna 251 or the second antenna 252. The second switching circuit 242 may be configured to selectively connect the second RFFE module 232 to the first antenna 251 or the second antenna 252.

According to an example embodiment, the electronic device 101 may further include a third switching circuit 243 connected to a first path between the first switching circuit 241 and the first antenna 251 and a fourth switching circuit 244 connected to a second path between the second switching circuit 242 and the second antenna 252. The third switching circuit 243 may be disposed on the first PCB. The fourth switching circuit 244 may be disposed on the second PCB.

According to an example embodiment, the first RFFE module 231 may include a transmission/reception module for transmission signal processing and reception signal processing. The second RFFE module 232 may include a reception module for reception signal processing. The first antenna 251 may be used for transmission of a signal while the first RFFE module 231 is connected to the first antenna 251 and the second RFFE module 232 is connected to the second antenna 252. The second antenna 252 may be used for transmission of a signal while the first RFFE module 231 is connected to the second antenna 252 and the second RFFE module 232 is connected to the first antenna 251. A distance between the second RFFE module 232 and the second antenna 252 may be shorter than a distance between the RF transceiver 220 and the second RFFE module 232.

According to an example embodiment, the electronic device 101 may further include a hinge structure connecting the first housing and the second housing. At least one of an electrical path between the RF transceiver 220 and the second RFFE module 232, an electrical path between the first switching circuit 241 and the fourth switching circuit 244, or an electrical path between the second switching circuit 242 and the third switching circuit 243 may be formed across the hinge structure.

According to an example embodiment, a portable communication device may include a plurality of antennas including a first antenna and a second antenna configured to transmit or receive a signal corresponding to a designated frequency band, an RF transceiver, a plurality of RFFE modules including a first RFFE module electrically connected to the RF transceiver and configured to transmit or receive the signal and a second RFFE module configured to receive the signal, and a plurality of switches including a first switch and a second switch. The first switch may be configured to selectively connect the first RFFE module to the first antenna or the second antenna, and the second switch may be configured to selectively connect the second RFFE module to the first antenna or the second antenna.

According to an example embodiment, at least one of the first switch and the second switch may be formed as a single pole double throw (SPDT) switch.

According to an embodiment, the plurality of switches may further include a third switch and a fourth switch. The third switch may be configured to selectively connect the second switch to the first antenna, and the fourth switch may be configured to selectively connect the first switch to the second antenna.

According to an example embodiment, at least one of the third switch and the fourth switch may be formed as a single pole single throw (SPST) switch.

According to an example embodiment, the third switch may be formed as an SPDT including a first end connected to the second switch, a second end connected to a path between the first antenna and the first switch, and a third end connected to a first stub circuit.

According to an example embodiment, the fourth switch may be formed as an SPDT including a first end connected to the first switch, a second end connected to a path between the second antenna and the second switch, and a third end connected to a second stub circuit.

According to an example embodiment, the electronic device may include a first matching circuit connected between the first switch and the first end of the fourth switch.

According to an example embodiment, the electronic device may include a second matching circuit connected between the second switch and the first end of the fourth switch.

According to an example embodiment, a path length between the third switch and the second switch may be longer than a path length between the first switch and the first antenna. A path length between the fourth switch and the first switch may be longer than a path length between the second switch and the second antenna.

According to an example embodiment, the first RFFE module may be disposed closer to the first antenna than to the second antenna, and the second RFFE module may be disposed closer to the second antenna than to the first antenna.

According to an example embodiment, the electronic device may further include a housing. The first antenna and the second antenna may form a first conductive portion on an outer lateral surface of the housing, and a second conductive portion spaced apart from the first portion by a non-conductive portion.

According to an example embodiment, the first conductive portion may form a portion of a first side of the outer lateral surface, and the second conductive portion may form a portion of a second side opposite to the first side of the outer lateral surface.

According to an example embodiment, the electronic device may further include a hinge housing and a foldable housing including a first housing and a second housing foldable with respect to the hinge housing. The first antenna may form a portion of an outer lateral surface of the first housing, and the second antenna may form a portion of an outer lateral surface of the second housing.

According to an example embodiment, the electronic device may further include a first PCB included in the first housing and a second PCB included in the second housing. The RF transceiver, the first RFFE module, and the first switch may be disposed on the first PCB. The second RFFE module and the second switch may be disposed on the second PCB.

According to an example embodiment, when the foldable housing is unfolded, the second antenna may be disposed closer to the second RFFE module than to the first RFFE module.

According to an example embodiment, each of a first electrical path between the first antenna and the second switch and a second electrical path between the second antenna and the first switch may be disposed to cross the hinge housing.

According to an example embodiment, the housing structure may include a first housing and a second housing foldably coupled to each other, and the PCB and the second antenna may be disposed in the first housing and the first antenna may be disposed in the second housing.

According to an example embodiment, while the first antenna is connected to the first RFFE module through the first switch, the third switch may be configured to be switched-off with the second switch. While the second antenna is connected to the second RFFE module through the second switch, the fourth switch may be configured to be switched-off with the first switch.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device, comprising:
a plurality of antennas including a first antenna and a second antenna;
a radio frequency (RF) transceiver;
a first radio frequency front end (RFFE) module comprising circuitry electrically connected to the RF transceiver and configured to transmit and/or receive signals;
a second RFFE module comprising circuitry electrically connected to the RF transceiver and configured to receive signals;
a plurality of switching circuits including a first switching circuit connected to the first RFFE module and a second switching circuit connected to the second RFFE module,
wherein the first switching circuit is configured to selectively connect the first RFFE module to the first antenna in a first connection mode or to the second antenna in a second connection mode, and
wherein the second switching circuit is configured to selectively connect the second RFFE module to the second antenna in the first connection mode or to the first antenna in the second connection mode.

2. The electronic device of claim 1,
wherein the plurality of switching circuits includes:
a third switching circuit connected to a first path between the first switching circuit and the first antenna; and
a fourth switching circuit connected to a second path between the second switching circuit and the second antenna,
wherein the third switching circuit is configured to disconnect the first antenna and the second switching circuit electrically in the first connection mode and to connect the first antenna and the second switching circuit electrically in the second connection mode, and
wherein the fourth switching circuit is configured to disconnect the second antenna and the first switching circuit electrically in the first connection mode and to connect the second antenna and the first switching circuit electrically in the second connection mode.

3. The electronic device of claim 2,
wherein the first switching circuit comprises a single pole double throw (SPDT) switch configured to selectively connect the first RFFE module to the first antenna or the second antenna, and
wherein the second switching circuit comprises a SPDT switch configured to selectively connect the second RFFE module to the first antenna or the second antenna.

4. The electronic device of claim 2, further comprising:
a first matching circuit for the second antenna, connecting the first switching circuit and the fourth switching circuit,
wherein the first switching circuit comprises a first end connected to the first antenna and a second end connected to the second antenna, and
wherein the second end of the first switching circuit is connected to the second antenna through the first matching circuit and the fourth switching circuit.

5. The electronic device of claim 4, further comprising:
a second matching circuit for the first antenna, connecting the second switching circuit and the third switching circuit,
wherein the second switching circuit comprises a first end connected to the second antenna and a second end connected to the first antenna, and
wherein the second end of the second switching circuit is connected to the first antenna through the second matching circuit and the third switching circuit.

6. The electronic device of claim 5,
wherein the third switching circuit comprises a single pole single throw (SPST) switch configured to selectively connect the second switching circuit to the first antenna or the second antenna, and
wherein the fourth switching circuit comprises a SPST switch configured to selectively connect the first switching circuit to the first antenna or the second antenna.

7. The electronic device of claim 5, further comprising:
a first stub circuit connected to the third switching circuit; and
a second stub circuit connected to the fourth switching circuit,
wherein the third switching circuit comprises a first end connected to the second matching circuit of the second switching circuit and a second end connected to the first stub circuit, and
wherein the fourth switching circuit comprises a first end connected to the first matching circuit of the first switching circuit and a second end connected to the second stub circuit.

8. The electronic device of claim 7,
wherein the third switching circuit comprises a single pole double throw (SPDT) configured to selectively connect the first stub circuit to the first antenna or the second RFFE module to the first antenna, and
wherein the fourth switching circuit comprises a single pole double throw (SPDT) configured to selectively connect the second stub circuit to the second antenna or the first RFFE module to the second antenna.

9. The electronic device of claim 1,
wherein the first RFFE module comprises a transmission/reception (Tx/Rx) module comprising circuitry configured for transmission signal processing and reception signal processing,
wherein the second RFFE module comprises a reception module comprising circuitry configured for reception signal processing,
wherein, in the first connection mode, the first antenna is configured for transmission of signals, and
wherein, in the second connection mode, the second antenna is configured for transmission of signals.

10. The electronic device of claim 1,
wherein a distance between the first antenna and the first RFFE module is less than a distance between the second antenna and the first RFFE module, and
wherein a distance between the second antenna and the second RFFE module is less than a distance between the first antenna and the second RFFE module.

11. The electronic device of claim 1,
wherein a distance between the second antenna and the second RFFE module is less than a distance between the RF transceiver and the second RFFE module.

12. An electronic device, comprising:
a housing, wherein the housing comprises a first conductive portion and a second conductive portion formed on an outer lateral surface of the housing;
a radio frequency (RF) transceiver;
a first radio frequency front end (RFFE) module comprising circuitry electrically connected to the RF transceiver and configured to transmit or receive signals;
a second RFFE module comprising circuitry electrically connected to the RF transceiver and configured to receive signals;
a first switching circuit connected to the first RFFE module; and
a second switching circuit connected to the second RFFE module;
wherein the first switching circuit is configured to selectively connect the first RFFE module to the first conductive portion or to the second conductive portion, and
wherein the second switching circuit is configured to selectively connect the second RFFE module to the second conductive portion or to the first conductive portion.

13. The electronic device of claim 12, further comprising:
a first printed circuit board (PCB) on which the RF transceiver, the first RFFE module, and the first switching circuit are disposed;
a second PCB on which the second RFFE module and the second switching circuit are disposed; and
an interposer coupled between the first PCB and the second PCB.

14. The electronic device of claim 13, further comprising:
a first conductive member comprising a conductive material electrically connected to the second conductive portion and disposed on the second PCB;
another housing rotatably coupled to the housing;
a substrate included in the another housing;
a third conductive portion disposed on the substrate; and
a second conductive member comprising a conductive material electrically connected to the third conductive portion and disposed on the substrate,
wherein the third conductive portion is configured to radiate transmission signals of the first RFFE module through coupling between the first conductive member and the second conductive member.

15. The electronic device of claim 12,
wherein the first RFFE module comprises a transmission/reception (Tx/Rx) module comprising circuitry configured for transmission signal processing and reception signal processing,
wherein the second RFFE module comprises a reception module comprising circuitry configured for reception signal processing,
wherein, while the first RFFE module is connected to the first conductive portion and the second RFFE module is connected to the second conductive portion, the first conductive portion is configured for transmission of signals, and
wherein, while the first RFFE module is connected to the second conductive portion and the second RFFE module is connected to the first conductive portion, the second conductive portion is configured for transmission of signals.
wherein a distance between the second conductive portion and the second RFFE module is less than a distance between the RF transceiver and the second RFFE module.

16. The electronic device of claim 12, further comprising:
a first printed circuit board (PCB) on which the RF transceiver, the first RFFE module, and the second RFFE module are disposed;
a second PCB;
a connection member for connecting the first PCB and the second PCB; and
a tuning circuit for the first conductive portion, disposed on the second PCB,
wherein the first conductive portion is disposed on a first side of the housing, and
wherein the second conductive portion is disposed on a second side opposite to the first side of the housing.

17. An electronic device, comprising:
a first housing;
a second housing rotatably coupled to the first housing;
a first antenna included in the first housing;
a second antenna included in the second housing;
a first printed circuit board (PCB) included in the first housing;
a second PCB included in the second housing;
a radio frequency (RF) transceiver disposed on the first PCB;
a first radio frequency front end (RFFE) module disposed on the first PCB, electrically connected to the RF transceiver, and configured to transmit or receive signals;
a second RFFE module disposed on the second PCB, electrically connected to the RF transceiver, and configured to receive signals;
a first switching circuit disposed on the first PCB and connected to the first RFFE module; and
a second switching circuit disposed on the second PCB and connected to the second RFFE module;
wherein the first switching circuit is configured to connect the first RFFE module selectively to the first antenna or to the second antenna, and
wherein the second switching circuit is configured to connect the second RFFE module selectively to the second antenna or to the first antenna.

18. The electronic device of claim 17, further comprising:
a third switching circuit connected to a first path between the first switching circuit and the first antenna; and
a fourth switching circuit connected to a second path between the second switching circuit and the second antenna,
wherein the third switching circuit is disposed on the first PCB, and
wherein the fourth switching circuit is disposed on the second PCB.

19. The electronic device of claim 17,
wherein the first RFFE module comprises a transmission/reception (Tx/Rx) module for transmission signal processing and reception signal processing,
wherein the second RFFE module comprises reception signal processing,
wherein, while the first RFFE module is connected to the first antenna and the second RFFE module is connected to the second antenna, the first antenna is used for transmission of signals, and
wherein, while the first RFFE module is connected to the second antenna and the second RFFE module is connected to the first antenna, the second antenna is used for transmission of signals.
wherein a distance between the second antenna and the second RFFE module is shorter than a distance between the RF transceiver and the second RFFE module.

20. The electronic device of claim 17, further comprising:
a hinge structure connecting the first housing and the second housing,
wherein at least one of an electrical path between the RF transceiver and the second RFFE module, an electrical path between the first switching circuit and the fourth switching circuit, or an electrical path between the second switching circuit and the third switching circuit is formed across the hinge structure.
